(19) United States
(12) Patent Application Publication
(10) Pub. No.: US 2026/0040972 A1
(43) Pub. Date: Feb. 5, 2026

(54) INTERPOSER, SEMICONDUCTOR PACKAGE INCLUDING INTERPOSER AND METHOD FOR MANUFACTURING THE SAME

(71) Applicant: SAMSUNG ELECTRONICS CO., LTD., Suwon-si (KR)

(72) Inventors: MyungDo CHO, Suwon-si (KR); Wooseok PARK, Suwon-si (KR); Jieun PARK, Suwon-si (KR); Younchan CHOI, Suwon-si (KR); Jaeyoung CHOI, Suwon-si (KR)

(21) Appl. No.: 19/013,809

(22) Filed: Jan. 8, 2025

(30) Foreign Application Priority Data
Aug. 2, 2024 (KR) 10-2024-0103286

(51) Int. Cl. H01L 23/498; H01L 23/538; H10B 80/00

(52) U.S. Cl. CPC H01L 23/49827; H01L 23/49816; H01L 23/49838; H01L 23/5384; H10B 80/00

(57) ABSTRACT

An interposer may include a redistribution structure, a bridge die on the redistribution structure, and a plurality of conductive posts on the redistribution structure, and the redistribution structure may include a dielectric layer, a plurality of redistribution lines in the dielectric layer, a plurality of vias on the plurality of redistribution lines in the dielectric layer, a plurality of first bonding pads on the dielectric layer and the plurality of vias with each connected to the bridge die, and a plurality of second bonding pads on the dielectric layer and the plurality of vias and connected to the plurality of conductive posts, respectively, the number of vias between each of the plurality of redistribution lines and a corresponding first bonding pad may be two or more, and the number of vias between each of the plurality of redistribution lines and a corresponding second bonding may be one.

### CROSS-REFERENCE TO RELATED APPLICATION

This application claims priority to and the benefit of Korean Patent Application No. 10-2024-0103286, filed in the Korean Intellectual Property Office on Aug. 2, 2024, the entire contents of which are incorporated herein by reference.

### BACKGROUND

The present disclosure relates to an interposer, a semiconductor package including the interposer, and a method for manufacturing the same.

With the demands for smaller and lighter electronic devices, the semiconductor industry has been seeking to make semiconductor chips to be mounted in electronic devices smaller, lighter, and thinner while making semiconductor chips have higher speed, more functions, and higher capacity. Accordingly, semiconductor chips have increasingly had input/output (I/O) terminals with finer pitches, and since it is technically and physically very difficult to connect fine-pitch I/O terminals of such semiconductor chips directly to general-pitch I/O terminals of substrates, redistribution layer (RDL) interposers have been developed and used as intermediate media for electrically connecting fine-pitch I/O terminals of semiconductor chips to general-pitch I/O terminals of substrates.

A redistribution layer interposer may have a structure which includes a lower redistribution structure and an upper redistribution structure including circuit wiring lines designed so as to be able to connect fine-pitch I/O terminals of a semiconductor chip to general-pitch I/O terminals of a substrate, and may include conductive posts and a bridge die between the lower redistribution structure and the upper redistribution structure.

The bridge die may have a wiring layer including signal lines designed to transfer signals between semiconductor chips, and through-silicon vias for transferring signals in the vertical direction, and when wiring layers and through-silicon vias are added as needed, the thickness of the bridge die increases, and as the thickness of the bridge die increases, the height of conductive posts also increases. However, in order to form conductive posts having the increased height, the same processes such as exposure, development, etching, and deposition should be additionally performed, and accordingly, the turnaround time (TAT) increases. Further, the repetition of these processes and an increased aspect ratio of conductive posts may cause a decrease in the yield of redistribution layer interposers. In order to solve these problems, the height of conductive posts may be reduced by forming bonding pads below the conductive posts. However, since the bonding pads which are formed below the conductive posts have a larger size than bonding pads which are formed below the bridge die, the volume difference between the bonding pads which are formed below the conductive posts and the bonding pads which are formed below the bridge die may cause a problem that the process variation of the bonding pads worsens in the course of performing an electroplating process for forming the bonding pads.

Also, the redistribution layer interposer has a structure in which the bridge die is disposed on the bonding pads of the lower redistribution structure and the bridge die is covered on the lower redistribution structure by a molding material. However, due to this structure of the redistribution layer interposer, stress caused by the differences in the coefficients of thermal expansion (CTEs) of the material of the molding material, the conductive material of the bonding pads, and the dielectric of the lower redistribution structure may be applied to the contact points of the molding material, the bonding pads, and the lower redistribution structure, and accordingly, the mechanical reliability of the redistribution layer interposer may deteriorate.

Further, the redistribution lines of the lower redistribution structure of the redistribution layer interposer are formed by performing an electroplating process. When the size of openings for forming the redistribution lines is large, the openings may not be fully filled even after the electroplating process is performed, and thus, the redistribution lines may have an undulated morphology. This affects fine conductive pattern formation in the subsequent processes, and may cause deterioration of the reliability of the redistribution layer interposer.

### SUMMARY

The present disclosure provides an interposer which includes a lower redistribution structure including under-bump metallurgy (UBM) pads, redistribution lines, first bonding pads that are connected to a bridge die, second bonding pads that are connected to conductive posts, wherein multiple vias are disposed between each of the UBM pads and each of the redistribution lines, multiple vias are disposed between each of the redistribution lines and each of the first bonding pads, and one via is disposed between each of the redistribution lines and each of the plurality of second bonding pads.

An interposer according to example embodiments may include a redistribution structure, a bridge die on the redistribution structure, and a plurality of conductive posts adjacent the bridge die and on the redistribution structure, and the redistribution structure may include a dielectric layer, a plurality of redistribution lines in the dielectric layer, a plurality of vias on the plurality of redistribution lines and in the dielectric layer, a plurality of first bonding pads on the dielectric layer and the plurality of vias and each of the plurality of first bonding pads is connected to the bridge die, and a plurality of second bonding pads on the dielectric layer and the plurality of vias and adjacent the plurality of first bonding pads, and each of the plurality of second bonding pads is connected to a corresponding conductive post of the plurality of conductive posts, and the number of vias disposed between each of the plurality of redistribution lines and a corresponding first bonding pad of the plurality of first bonding pads may be two or more, and the number of vias disposed between each of the plurality of redistribution lines and a corresponding second bonding pad of the plurality of second bonding pads may be one.

An interposer according to example embodiments may include a first redistribution structure, a bridge die on the first redistribution structure, a plurality of conductive posts adjacent the bridge die and on the first redistribution structure, a second redistribution structure on the bridge die and the plurality of conductive posts, and a molding material between the first redistribution structure and the second redistribution structure so as to at least partially cover the bridge die and the plurality of conductive posts, and the first redistribution structure may include a dielectric layer, a plurality of UBM pads in the dielectric layer, a plurality of first vias on the plurality of UBM pads in the dielectric layer, a plurality of redistribution lines on the plurality of first vias and in the dielectric layer, a plurality of second vias on the plurality of redistribution lines and in the dielectric layer, a plurality of third vias on the plurality of redistribution lines and in the dielectric layer, and adjacent the plurality of second vias, a plurality of first bonding pads on the dielectric layer and the plurality of second vias with each of the plurality of first bonding pads connected to the bridge die, and a plurality of second bonding pads on the dielectric layer and the plurality of third vias and adjacent the plurality of first bonding pads, with each of the plurality of second bonding pads connected to a corresponding conductive post of the plurality of conductive posts, and the number of first vias disposed between each of the plurality of UBM pads and a corresponding redistribution line of the plurality of redistribution lines may be two or more, and the number of second vias disposed between each of the plurality of redistribution lines and a corresponding first bonding pad of the plurality of first bonding pads may be two or more, and the number of third vias disposed between each of the plurality of redistribution lines and a corresponding second bonding pad of the plurality of second bonding pads may be one.

A semiconductor package according to example embodiments may include a redistribution layer interposer, a first semiconductor die on the redistribution layer interposer, and a second semiconductor die adjacent the first semiconductor die on the redistribution layer interposer, and the redistribution layer interposer may include a first redistribution structure, a bridge die on the first redistribution structure, a plurality of conductive posts adjacent the bridge die on the first redistribution structure, a second redistribution structure on the bridge die and the plurality of conductive posts, and a molding material between the first redistribution structure and the second redistribution structure and at least partially covering the bridge die and the plurality of conductive posts, and the first redistribution structure may include a dielectric layer, a plurality of redistribution lines in the dielectric layer, a plurality of vias on the plurality of redistribution lines and in the dielectric layer, a plurality of first bonding pads on the dielectric layer and the plurality of vias and each of the plurality of first bonding pads is connected to the bridge die, and a plurality of second bonding pads on the dielectric layer and the plurality of vias and adjacent the plurality of first bonding pads, and each of the plurality of second bonding pads is connected to a corresponding conductive post of the plurality of conductive posts, and the number of vias disposed between each of the plurality of redistribution lines and a corresponding first bonding pad of the plurality of first bonding pads may be two or more, and the number of vias disposed between each of the plurality of redistribution lines and a corresponding second bonding pad of the plurality of second bonding pads may be one.

Multiple vias may be disposed between each of the redistribution lines and each of the first bonding pads below the bridge die, and multiple vias may be disposed between each of the redistribution lines and each of the second bonding pads below the conductive posts. Accordingly, the differences between the volumes of the first bonding pads below the bridge die and the volumes of the second bonding pads below the conductive posts can be offset by the addition of the multiple vias in the course of performing an electroplating process on a first bonding pad and multiple vias, and a second bonding pad and one via simultaneously, and it is possible to prevent the process variation from worsening when the electroplating process is performed.

Multiple vias may be disposed between each of the redistribution lines and each of the first bonding pads of the bridge die. Accordingly, a first bonding pad can be structurally supported by multiple vias, and stress which is caused at the contact points of the molding material, the bonding pad, and the lower redistribution structure by the differences of the coefficients of thermal expansion (CTEs) of the materials of them can be alleviated.

Multiple vias may be disposed between each of the UBM pads and each of the redistribution lines. Since it is possible to improve the process variation of an electroplating process as the volume of a portion which is a subject of the electroplating increases, it is possible to increase the volume of the subject to be subjected to the electroplating process by adding multiple vias, thereby preventing a redistribution line from having an undulated morphology, and thus, it is possible to improve the process variation of the electroplating process and improve the reliability of the redistribution layer interposer.

### BRIEF DESCRIPTION OF THE DRAWINGS

FIG. 1 is a cross-sectional view illustrating a semiconductor package including an interposer of an example embodiment.

FIG. 2 is a cross-sectional view illustrating a region A of the interposer of FIG. 1.

FIG. 3 is a plan view illustrating a portion of the upper surface of a redistribution line of the interposer of the example embodiment of FIG. 2.

FIG. 4 is a plan view illustrating a portion of the upper surface of a redistribution line of the interposer of the example embodiment of FIG. 2.

FIG. 5 is a plan view illustrating a portion of the upper surface of a redistribution line of the interposer of the example embodiment of FIG. 2.

FIGS. 6 to 24 are cross-sectional views for explaining a method of manufacturing the interposer of FIG. 1.

FIGS. 25 to 30 are cross-sectional views for explaining a method of manufacturing the semiconductor package of FIG. 1.

### DETAILED DESCRIPTION

In the following detailed description, only certain example embodiments of the present disclosure have been shown and described, simply by way of illustration. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, the size and thickness of each configuration shown in the drawings may be arbitrarily shown for understanding and ease of description, but the present disclosure is not limited thereto.

Throughout this specification, when a part or element is referred to as being “connected” to another part or element, it may be directly connected to the other part or element, or may be connected to the other part or element indirectly with any other elements interposed therebetween. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “above” or “on” a reference portion, the element is located above or below the reference portion, and it does not necessarily mean that the element is located “above” or “on” in a direction opposite to gravity.

Further, in the entire specification, when it is referred to as “on a plane”, it means when a target part is viewed from above, and when it is referred to as “on a cross-section”, it means when the cross-section obtained by cutting a target part vertically is viewed from the side.

Hereinafter, an interposer 10 of an example embodiment, a semiconductor package 100 including the interposer 10, and methods of manufacturing the interposer 10 and the semiconductor package 100 will be described with reference to the drawings.

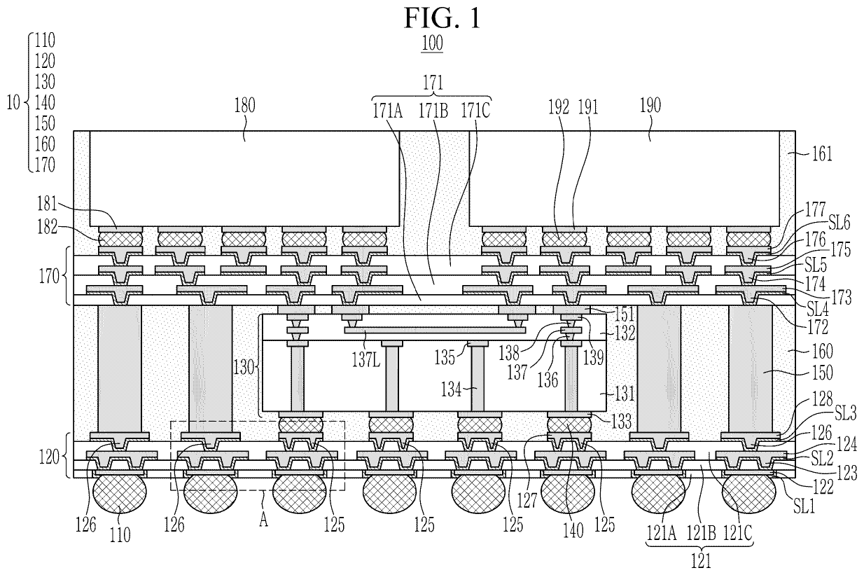

FIG. 1 is a cross-sectional view illustrating the semiconductor package 100 including the interposer 10 of the example embodiment.

Referring to FIG. 1, the semiconductor package 100 may include the interposer 10, a first semiconductor die 180, a second semiconductor die 190, and a second molding material 161. In example embodiments, the semiconductor package 100 may be manufactured based on a fan-out wafer-level packaging (FOWLP) or fan-out panel-level packaging (FOPLP) technology.

The interposer 10 may include external connection members 110, a lower redistribution structure (a first redistribution structure) 120, a bridge die 130, first connection members 140, conductive posts 150, connection terminals 151, a first molding material 160, and an upper redistribution structure (a second redistribution structure) 170. In example embodiments, the interposer 10 may include a redistribution layer (RDL) interposer. In example embodiments, the interposer 10 may be manufactured based on a fan-out wafer-level packaging (FOWLP) or fan-out panel-level packaging (FOPLP) technology.

The external connection members 110 may be disposed on the lower surface of the lower redistribution structure 120. Each of the external connection members 110 may be electrically connected to each of the under-bump metallurgy (UBM) pads 122 of the lower redistribution structure 120, respectively. The external connection members 110 may electrically connect the semiconductor package 100 to an external device.

The lower redistribution structure 120 may be disposed on the external connection members 110. The lower redistribution structure 120 may include a first dielectric (a dielectric) or first dielectric layer 121, the UBM pads 122, first vias 123, first redistribution lines 124, second vias 125, and third vias 126 that are positioned inside the first dielectric 121, and first bonding pads 127 and second bonding pads 128 that are positioned on the first dielectric layer 121. In other example embodiments, a lower redistribution structure 120 including more or less UBM pads, redistribution lines, vias, and bonding pads may be included in the scope of the present disclosure.

The first dielectric 121 may protect and insulate the UBM pads 122, the first vias 123, the first redistribution lines 124, the second vias 125, and the third vias 126. On the upper surface of the first dielectric 121, the first bonding pads 127, the second bonding pads 128, and the first molding material 160 may be disposed. On the lower surface of the first dielectric 121, the external connection members 110 may be disposed. The first dielectric 121 may include a first dielectric layer 121A, a second dielectric layer 121B, and a third dielectric layer 121C from the bottom in the order in which they are deposited in the manufacturing process. In the interposer 10 of the final product, the boundaries of the first dielectric layer 121A to the third dielectric layer 121C may have disappeared, and thus, they may be seen as an integral first dielectric 121 without being distinguished from each other.

The UBM pads 122 may be positioned inside the first dielectric layer 121A of a first level. The UBM pads 122 or side surfaces thereof may be surrounded by the first dielectric layer 121A. Each of the UBM pads 122 may be disposed between two or more first vias (two or more first vias may be referred to as first multiple vias) 123 of the first vias 123 of a second level on the first level and each of the external connection members 110. Each of the UBM pads 122 may electrically connect two or more first vias 123 of the first vias 123 to each of the external connection members 110. Between the side surface of each of the UBM pads 122 and first dielectric layer 121A and on a portion of the lower surface of each of the UBM pads 122, a seed metal layer SL1 may be positioned.

The first vias 123 may be positioned inside the second dielectric layer 121B of the second level. The first vias 123 or side surfaces thereof may be surrounded by the second dielectric layer 121B. Two or more first vias 123 of the first vias 123 may be disposed between each of the UBM pads 122 and a corresponding first redistribution line of the first redistribution lines 124 of a third level on the second level. In example embodiments, the number of two or more first vias 123 may be four. Two or more first vias 123 of the first vias 123 may electrically connect each of the first redistribution lines 124 to a corresponding UBM pad of the UBM pads 122. Between the side surface of each of the first vias 123 and the second dielectric layer 121B and between the lower surface of each of the first vias 123 and the upper surface of each of the UBM pads 122, a seed metal layer SL2 may be positioned.

The first redistribution lines 124 may be positioned inside the third dielectric layer 121C of the third level. The first redistribution lines 124 or side surfaces thereof may be surrounded by the third dielectric layer 121C. Each of the first redistribution lines 124 may be disposed between two or more first vias 123 of the first vias 123 and two or more second vias (two or more second vias may be referred to as second multiple vias) 125 of the second vias 125, or between two or more first vias 123 of the first vias 123 and each of the third vias 126. Each of the first redistribution lines 124 may electrically connect each of two or more second vias 125 of the second vias 125 to two or more first vias 123 of the first vias 123, or may electrically connect each of the third vias 126 to two or more first vias 123 of the first vias 123. Between the lower surface of each of the first redistribution lines 124 and the second dielectric layer 121B of the second level, a seed metal layer SL2 may be positioned.

The second vias 125 may be positioned inside the third dielectric layer 121C of the third level. The second vias 125 or side surfaces thereof may be surrounded by the third dielectric layer 121C. The second vias 125 may be positioned at the same vertical level as that of the third vias 126. The second vias 125 may be positioned adjacent or next to the third vias 126. Two or more second vias 125 of the second vias 125 may be disposed between each of the first redistribution lines 124 and a corresponding first bonding pad of the first bonding pads 127. In example embodiments, the number of two or more second vias 125 may be four. Two or more second vias 125 of the second vias 125 may electrically connect each of the first bonding pads 127 to a corresponding first redistribution line of the first redistribution lines 124. Between the side surface of each of the second vias 125 and the third dielectric layer 121C and between the lower surface of each of the second vias 125 and the upper surface of each of the first redistribution lines 124, a seed metal layer SL3 may be positioned.

The third vias 126 may be positioned inside the third dielectric layer 121C of the third level. The third vias 126 or side surfaces thereof may be surrounded by the third dielectric layer 121C. The third vias 126 may be positioned at the same vertical level as that of the second vias 125. The third vias 126 may be positioned adjacent or next to the second vias 125. Each of the third vias 126 may be disposed between each of the first redistribution lines 124 and each of the second bonding pads 128. Each of the third vias 126 may electrically connect each of the second bonding pads 128 to each of the first redistribution lines 124. Between the side surface of each of the third vias 126 and the third dielectric layer 121C and between the lower surface of each of the third vias 126 and the upper surface of each of the first redistribution lines 124, a seed metal layer SL3 may be positioned.

The first bonding pads 127 may be positioned on the third dielectric layer 121C of the third level. The first bonding pads 127 or side surfaces thereof may be surrounded by the first molding material 160. The first bonding pads 127 may be positioned adjacent or next to the second bonding pads 128. The first bonding pads 127 may be connected to a bridge die 130. Each of the first bonding pads 127 may be positioned between two or more second vias 125 of the second vias 125 and each of the first connection members 140. Each of the first bonding pads 127 may electrically connect each of the first connection members 140 to two or more second vias 125 of the second vias 125. Between the lower surface of each of the first bonding pads 127 and the third dielectric layer 121C of the third level, a seed metal layer SL3 may be positioned.

The second bonding pads 128 may be positioned on the third dielectric layer 121C of the third level. The second bonding pads 128 or side surfaces thereof may be surrounded by the first molding material 160. The second bonding pads 128 may be positioned adjacent or next to the first bonding pads 127. Each of the second bonding pads 128 may be connected to each of the conductive posts 150. Each of the second bonding pads 128 may be disposed between each of the third vias 126 and each of the conductive posts 150. Each of the second bonding pads 128 may electrically connect each of the conductive posts 150 to each of the third vias 126. Between the lower surface of each of the second bonding pads 128 and the third dielectric layer 121C of the third level, a seed metal layer SL3 may be positioned.

The bridge die 130 may be disposed on the lower redistribution structure 120. In example embodiments, the bridge die 130 may include a silicon bridge die. The bridge die 130 may electrically connect the first semiconductor die 180 to the second semiconductor die 190 through the upper redistribution structure 170. Signals between the first semiconductor die 180 and the second semiconductor die 190 may be routed through the bridge die 130. The bridge die 130 may electrically connect the upper redistribution structure 170 to the lower redistribution structure 120.

The bridge die 130 may include a die base 131 and a front side structure 132. The die base 131 may be a die formed from a wafer. In example embodiments, the die base 131 may comprise silicon or any other semiconductor material. The die base 131 may include through-silicon vias 134 and wiring lines 135.

The through-silicon vias 134 and the wiring lines 135 may be disposed inside the die base 131. The through-silicon vias 134 and the wiring lines 135 may be disposed between the front side structure 132 and each of first connection pads 133. Each of the through-silicon vias 134 and each of the wiring lines 135 may electrically connect the front side structure 132 to each of the first connection pads 133 in the vertical direction. In example embodiments, the through-silicon vias 134 may comprise at least one of tungsten, aluminum, copper, and alloys thereof. In example embodiments, the wiring lines 135 may comprise at least one of copper, aluminum, tungsten, nickel, gold, tin, titanium, and alloys thereof. In other example embodiments, a die base 131 including more or less through-silicon vias and wiring lines may be included in the scope of the present disclosure.

The front side structure 132 may be positioned on the die base 131. The front side structure 132 may include an inter-metal dielectric (IMD), and first contact plug 136, first wiring lines 137, second contact plugs 138, and second wiring line 139 that are positioned inside the inter-metal dielectric (IMD). The first contact plugs 136, the first wiring lines 137, the second contact plugs 138, and the second wiring lines 139 may be disposed sequentially from the bottom, and may constitute vertical signal routing paths which electrically connect the connection terminals 151, which are connected to the upper redistribution structure 170, to the die base 131. The first wiring lines 137L, the second contact plugs 138, and the second wiring lines 139 may be disposed sequentially from the bottom, and may constitute a horizontal signal routing path which electrically connects the first semiconductor die 180 to the second semiconductor die 190. In example embodiments, the inter-metal dielectric (IMD) may comprise SiO₂, SiOC, SiOH, SiOCH, or a low-dielectric constant insulating layer (a low-k dielectric layer). In example embodiments, each of the first contact plugs 136, the first wiring lines 137, the second contact plugs 138, and the second wiring lines 139 may comprise at least one of copper, aluminum, tungsten, nickel, gold, tin, titanium, and alloys thereof.

Each of the first connection pads 133 may be disposed between each of the first connection members 140 and each of through-silicon vias 134. Each of the first connection pads 133 may electrically connect each of the through-silicon vias 134 to each of the first connection members 140. Each of the first connection members 140 may be disposed between each of the first bonding pads 127 and each of the first connection pads 133. Each of the first connection members 140 may electrically connect each of the first connection pads 133 to each of the first bonding pads 127.

The conductive posts 150 may be disposed on the lower redistribution structure 120. The conductive posts 150 may be disposed around the bridge die 130. The conductive posts 150 may be disposed adjacent or next to the bridge die 130. Each of the conductive posts 150 may be disposed between each of the second bonding pads 128 of the lower redistribution structure 120 and each of fourth redistribution vias 172 of the upper redistribution structure 170. Each of the conductive posts 150 may electrically connect each of the fourth redistribution vias 172 of the upper redistribution structure 170 to each of the second bonding pads 128 of the lower redistribution structure 120. The conductive posts 150 may be disposed so as to pass through the first molding material 160. The side surfaces of the conductive posts 150 may be surrounded by the first molding material 160.

The connection terminals 151 may be disposed on the bridge die 130. Each of the connection terminals 151 may be disposed between each of the second wiring lines 139 and the fourth redistribution vias 172 of the upper redistribution structure 170. Each of the connection terminals 151 may electrically connect each of the fourth redistribution vias 172 of the upper redistribution structure 170 to each of the second wiring lines 139. The side surfaces of the connection terminals 151 may be surrounded by the first molding material 160. In example embodiments, the connection terminals 151 may comprise at least one of copper, aluminum, tungsten, nickel, gold, silver, chromium, antimony, tin, titanium, and alloys thereof.

The first molding material 160 may at least partially cover or surround the first bonding pads 127, the second bonding pads 128, the bridge die 130, the first connection members 140, the conductive posts 150, and the connection terminals 151 between the lower redistribution structure 120 and the upper redistribution structure 170. The first molding material 160 may protect the first bonding pads 127, the second bonding pads 128, the bridge die 130, the first connection members 140, the conductive posts 150, and the connection terminals 151 from the external environment.

The upper redistribution structure 170 may be disposed on the conductive posts 150, on the connection terminals 151, and on the first molding material 160. The upper redistribution structure 170 may include a second dielectric or second dielectric layer 171, fourth vias 172, second redistribution lines 173, fifth vias 174, third redistribution lines 175, and sixth vias 176 that are positioned inside the second dielectric 171, and third bonding pads 177 that are positioned on the second dielectric 171. In other example embodiments, an upper redistribution structure 170 including more or less redistribution lines, vias, and bonding pads may be included in the scope of the present disclosure.

The second dielectric 171 may protect and insulate the fourth vias 172, the second redistribution lines 173, the fifth vias 174, the third redistribution lines 175, and the sixth vias 176. On the upper surface of the second dielectric 171, the third bonding pads 177 and a second molding material 161 may be disposed. On the lower surface of the second dielectric 171, the conductive posts 150, the connection terminals 151, and the first molding material 160 may be disposed. The second dielectric 171 may include a fourth dielectric layer 171A, a fifth dielectric layer 171B, and a sixth dielectric layer 171C from the bottom in the order in which they are deposited in the manufacturing process. In the interposer 10 of the final product, the boundaries of the fourth dielectric layer 171A to the sixth dielectric layer 171C may have disappeared, and thus, they may be seen as an integral second dielectric 171 without being distinguished from each other.

The fourth vias 172 may be positioned inside the fourth dielectric layer 171A of a first level. The fourth vias 172 or side surfaces thereof may be surrounded by the fourth dielectric layer 171A. Each of the fourth vias 172 may be disposed between each of the conductive posts 150 and each of the second redistribution lines 173 of a second level on the first level, or between each of the connection terminals 151 and each of the second redistribution lines 173. Each of the fourth vias 172 may electrically connect each of the second redistribution lines 173 to each of the conductive posts 150, or may electrically connect each of the second redistribution lines 173 to each of the connection terminals 151. Between the side surface of each of the fourth vias 172 and the fourth dielectric layer 171A, between the lower surface of each of the fourth vias 172 and the upper surface of each of the conductive posts 150, and between the lower surface of each of the fourth vias 172 and the upper surface of each of the connection terminals 151, a seed metal layer SL4 may be positioned.

The second redistribution lines 173 may be positioned inside the fifth dielectric layer 171B of the second level. The second redistribution lines 173 or side surfaces thereof may be surrounded by the fifth dielectric layer 171B. Each of the second redistribution lines 173 may be disposed between each of the fourth vias 172 and each of the fifth vias 174. Each of the second redistribution lines 173 may electrically connect each of the fifth vias 174 to each of the fourth vias 172. Between the lower surface of each of the second redistribution lines 173 and the fourth dielectric layer 171A of the first level, a seed metal layer SL4 may be positioned.

The fifth vias 174 may be positioned inside the fifth dielectric layer 171B of the second level. The fifth vias 174 or side surfaces thereof may be surrounded by the fifth dielectric layer 171B. Each of the fifth vias 174 may be disposed between each of the second redistribution lines 173 and each of the third redistribution lines 175. Each of the fifth vias 174 may electrically connect each of the third redistribution lines 175 to each of the second redistribution lines 173. Between the side surface of each of the fifth vias 174 and the fifth dielectric layer 171B and between the lower surface of each of the fifth vias 174 and the upper surface of each of the second redistribution lines 173, a seed metal layer SL5 may be positioned.

The third redistribution lines 175 may be positioned inside the sixth dielectric layer 171C of a third level on the second level. The third redistribution lines 175 or side surfaces thereof may be surrounded by the sixth dielectric layer 171C. Each of the third redistribution lines 175 may be disposed between each of the fifth vias 174 and each of the sixth vias 176. Each of the third redistribution lines 175 may electrically connect each of the sixth vias 176 to each of the fifth vias 174. Between the lower surface of each of the third redistribution lines 175 and the fifth dielectric layer 171B of the second level, a seed metal layer SL5 may be positioned.

The sixth vias 176 may be positioned inside the sixth dielectric layer 171C of a third level. The sixth vias 176 or side surfaces thereof may be surrounded by the sixth dielectric layer 171C. Each of the sixth vias 176 may be disposed between each of the third redistribution lines 175 and each of the third bonding pads 177. Each of the sixth vias 176 may electrically connect each of the third bonding pads 177 to each of the third redistribution lines 175. Between the side surface of each of the sixth vias 176 and the sixth dielectric layer 171C and between the lower surface of each of the sixth vias 176 and the upper surface of each of the third redistribution lines 175, a seed metal layer SL6 may be positioned.

The third bonding pads 177 may be positioned on the sixth dielectric layer 171C of the third level. The third bonding pads 177 or side surfaces thereof may be surrounded by the second molding material 161. Each of the third bonding pads 177 may be disposed between each of the sixth vias 176 and each of second connection members 182, or between each of the sixth vias 176 and each of third connection members 192. Each of the third bonding pads 177 may electrically connect each of the second connection members 182 to each of the sixth vias 176, or may electrically connect each of the third connection members 192 to each of the sixth vias 176. Between the lower surface of each of the third bonding pads 177 and the sixth dielectric layer 171C of the third level, a seed metal layer SL6 may be positioned.

The first semiconductor die 180 may be positioned on the upper redistribution structure 170. The first semiconductor die 180 may be disposed side by side with the second semiconductor die 190. In example embodiments, the first semiconductor die 180 may include an application processor (AP). The first semiconductor die 180 may be a chiplet manufactured by dividing an application processor (AP) according to a use or according to a process which is applied. In example embodiments, the first semiconductor die 180 may include at least one of central processing units (CPUs), graphic processing units (GPUs), signal processors, network processors, and codecs.

Each of second connection pads 181 may be disposed between each of the wiring lines of the first semiconductor die 180 and each of the second connection members 182. Each of the second connection pads 181 may electrically connect each of the wiring lines of the first semiconductor die 180 to each of the second connection members 182. Each of the second connection members 182 may be disposed between each of the third bonding pads 177 and each of the second connection pads 181. Each of the second connection members 182 may electrically connect each of the second connection pads 181 to each of the third bonding pads 177.

The second semiconductor die 190 may be disposed on the upper redistribution structure 170. The second semiconductor die 190 may be disposed side by side with the first semiconductor die 180. In example embodiments, the second semiconductor die 190 may include an application processor (AP). The second semiconductor die 190 may be a chiplet manufactured by dividing an application processor (AP) according to a use or according to a process which is applied. In example embodiments, the second semiconductor die 190 may include at least one of central processing units (CPUs), graphic processing units (GPUs), signal processors, network processors, and codecs. In example embodiments, the second semiconductor die 190 may include a memory die. In example embodiments, the second semiconductor die 190 may include a DRAM or a high bandwidth memory (HBM).

Each of third connection pads 191 may be disposed between each of the wiring lines of the second semiconductor die 190 and each of the third connection members 192. Each of the third connection pads 191 may electrically connect each of the wiring lines of the second semiconductor die 190 to each of the third connection members 192. Each of the third connection members 192 may be disposed between each of the third bonding pads 177 and each of the third connection pads 191. Each of the third connection members 192 may electrically connect each of the third connection pads 191 to each of the third bonding pads 177.

The second molding material 161 may at least partially cover or surround the third bonding pads 177, the first semiconductor die 180, the second connection pads 181, the second connection members 182, the second semiconductor die 190, the third connection pads 191, and the third connection members 192 on the upper redistribution structure 170. The second molding material 161 may protect the third bonding pads 177, the first semiconductor die 180, the second connection pads 181, the second connection members 182, the second semiconductor die 190, the third connection pads 191, and the third connection members 192 from the external environment. The upper surface of the first semiconductor die 180 and the upper surface of the second semiconductor die 190 may be exposed from the second molding material 161 to the outside. The upper surface of the first semiconductor die 180 and the upper surface of the second semiconductor die 190 may be coplanar with the upper surface of the second molding material 161.

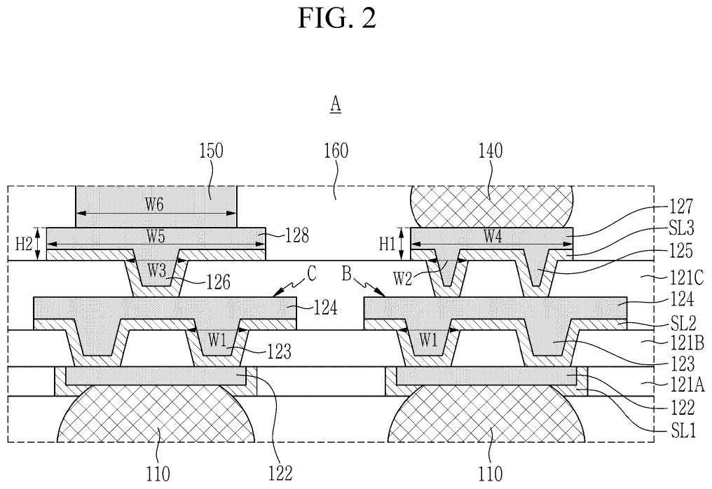

FIG. 2 is an enlarged cross-sectional view illustrating a region A of the interposer 10 of FIG. 1.

Referring to FIG. 2, the region A may include a portion of the lower redistribution structure 120, a portion of a first connection member 140, and a portion of a conductive post 150. The portion of the lower redistribution structure 120 may include a UBM pad 122, a first via 123, a first redistribution line 124, a second via 125, a third via 126, a first bonding pad 127, and a second bonding pad 128.

The number of first vias 123 which are disposed between one UBM pad 122 and one first redistribution line 124 may be two or more, and a plurality of first vias 123 may electrically connect one first redistribution line 124 to one UBM pad 122 in the vertical direction. One first redistribution line 124 and a plurality of first vias 123 which is connected to the one first redistribution line 124 may form an integral structure without interfaces.

The number of second vias 125 which are disposed between one first redistribution line 124 and one first bonding pad 127 may be two or more, and a plurality of second vias 125 may electrically connect one first bonding pad 127 to one first redistribution line 124 in the vertical direction. One first bonding pad 127 and a plurality of second vias 125 which is connected to the one first bonding pad 127 may form an integral structure without interfaces.

The number of third vias 126 which are disposed between one first redistribution line 124 and one second bonding pad 128 may be one, and one third via 126 may electrically connect one second bonding pad 128 to one first redistribution line 124 in the vertical direction. One second bonding pad 128 and one third via 126 which is connected to the one second bonding pad 128 may form an integral structure without an interface.

The upper surface of a first via 123 may have a first width W1 in the horizontal direction. The upper surface of a second via 125 may have a second width W2 in the horizontal direction. The upper surface of a third via 126 may have a third width W3 in the horizontal direction. The first width W1 may be larger than the second width W2. The third width W3 may be larger than the second width W2. The first width W1 may be equal to the third width W3. As used herein, the “upper surface” of a via may correspond to the interface between the via and the overlying redistribution line or bonding pad. The upper surface of the via and the lower surface of the overlying redistribution line or bonding pad may be coplanar.

A first bonding pad 127 may have a fourth width W4 in the horizontal direction and a first thickness H1 in the vertical direction. A second bonding pad 128 may have a fifth width W5 in the horizontal direction and a second thickness H2 in the vertical direction. A conductive post 150 may have a sixth width W6 in the horizontal direction. The fourth width W4 may be smaller than the fifth width W5. The fifth width W5 may be larger than the sixth width W6. The first thickness H1 may be equal to the second thickness H2.

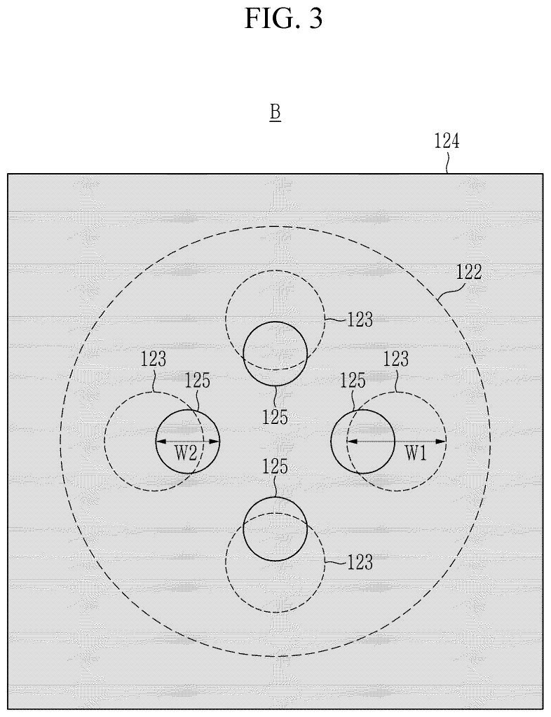

FIG. 3 is a plan view illustrating a portion of the upper surface B of a first redistribution line 124 of the interposer 10 of the example embodiment of FIG. 2.

Referring to FIG. 3, a plurality of first vias 123 may be disposed between one UBM pad 122 and one first redistribution line 124 positioned below the bridge die 130, and a plurality of second vias 125 may be disposed on one first redistribution line 124. The UBM pad 122 and the first vias 123 are shown by dotted lines, and the second vias 125 are shown by solid lines. The upper surface of each of the first vias 123 may have the first width W1 in the horizontal direction, and the upper surface of each of the second vias 125 may have the second width W2 in the horizontal direction, smaller than the first width W1. The footprints of the first vias 123 may overlap at least some portions of the footprints of the second vias 125.

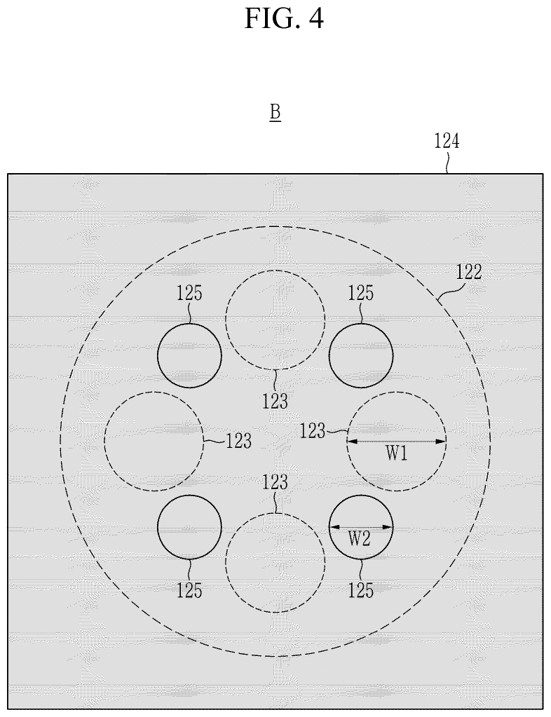

FIG. 4 is a plan view illustrating a portion of the upper surface B of a first redistribution line 124 of the interposer 10 of the example embodiment of FIG. 2.

Referring to FIG. 4, a plurality of first vias 123 may be disposed between one UBM pad 122 and one first redistribution line 124 positioned below the bridge die 130, and a plurality of second vias 125 may be disposed on one first redistribution line 124. The UBM pad 122 and the first vias 123 are shown by dotted lines, and the second vias 125 are shown by solid lines. The upper surface of each of the first vias 123 may have the first width W1 in the horizontal direction, and the upper surface of each of the second vias 125 may have the second width W2 in the horizontal direction, smaller than the first width W1. The footprints of the first vias 123 may not overlap the footprints of the second vias 125. In other example embodiments, the footprints of some of the first vias 123 may overlap the footprints of second vias 125, and the footprints of the others of the first vias 123 may not overlap the footprints of the second vias 125.

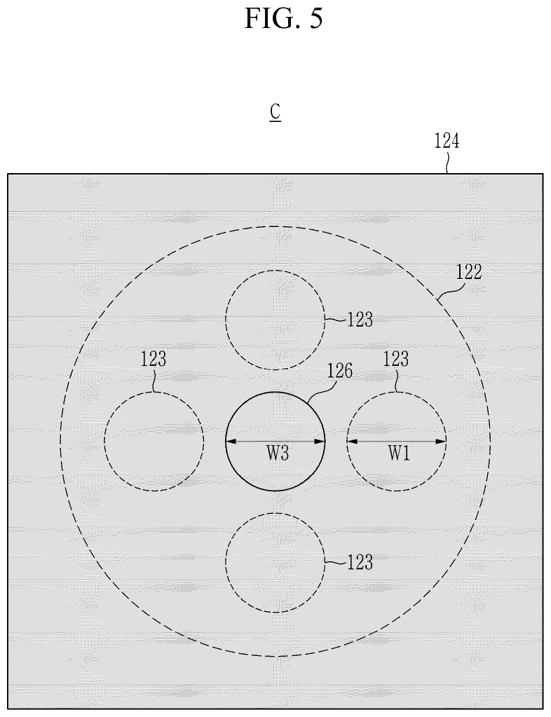

FIG. 5 is a plan view illustrating a portion of the upper surface C of a first redistribution line 124 of the interposer 10 of the example embodiment of FIG. 2.

Referring to FIG. 5, a plurality of first vias 123 may be disposed between a UBM pad 122 and a first redistribution line 124 positioned below the bridge die 130, and one third via 126 may be disposed on the first redistribution line 124. The UBM pad 122 and the first vias 123 are shown by dotted lines, and the third via 126 is shown by a solid line. The upper surface of each of the first vias 123 may have a first width W1 in the horizontal direction, and the upper surface of the third via 126 may have a third width W3 in the horizontal direction, equal to the first width W1. The footprints of the first vias 123 may not overlap the footprint of the third via 126. In other example embodiments, the footprints of the first vias 123 may overlap the footprint of the third via 126.

In the example embodiments of FIGS. 3, 4, and 5, each of the number of first vias 123 and the number of second vias 125 may be four. Four first vias 123 may provide structural stability to the routing path between one UBM pad 122 and one first redistribution line 124. Four second vias 125 may provide structural stability between one first redistribution line 124 and one first bonding pad 127.

In the example embodiments of FIGS. 3, 4, and 5, it is shown that the number of first vias 123 is four and the number of second vias 125 is four; however, the present disclosure is not limited thereto, and an interposer 10 including more or less first vias 123 and second vias 125 may be included in the scope of the present disclosure. Also, in the example embodiments of FIGS. 3, 4, and 5, it is shown that the cross-sectional shape in the horizontal direction of each of the UBM pad 122, the first vias 123, the second vias 125, and the third via 126 is circular; however, the present disclosure is not limited thereto, and an interposer 10 including a UBM pad 122, first vias 123, second vias 125, and a third via 126 having various cross-sectional shapes may be included in the scope of the present disclosure.

At the positions where the first molding material 160, the first bonding pads 127, and the first dielectric 121 of the lower redistribution structure 120 are in contact with each other, stress may be caused by the differences in the coefficients of thermal expansion (CTEs) of the material of the first molding material 160, the conductive material of the first bonding pads 127, and the organic material of the first dielectric 121 of the lower redistribution structure 120, and cracks may propagate. According to the present disclosure, the numbers of first vias 123 and second vias 125 are not limited as long as they can structurally and mechanically support the first bonding pad positioned below the bridge die 130. As described above, a plurality of first vias 123 and a plurality of second vias 125 may be disposed to alleviate stress which is caused by the differences in the coefficients of thermal expansion (CTEs) of the material of the first molding material 160, the conductive material of the first bonding pads 127, and the organic material of the first dielectric 121 of the lower redistribution structure 120, and improve the mechanical and structural reliability of the interposer 10.

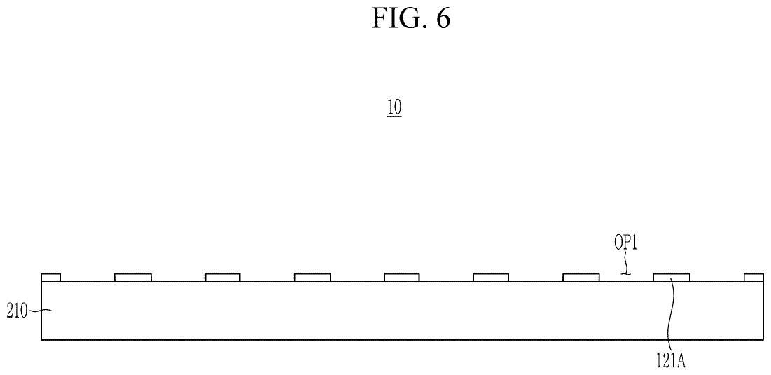

FIGS. 6 to 24 are cross-sectional views for explaining a method of manufacturing the interposer 10 of FIG. 1.

FIG. 6 is a cross-sectional view illustrating a step of depositing a first dielectric layer 121A on a carrier 210 and forming first openings OP1 in the first dielectric layer 121A.

Referring to FIG. 6, the carrier 210 may be provided. The carrier 210 may comprise, for example, a silicon-based material such as glass or silicon oxide, an organic material, or other materials such as aluminum oxide, any combination of these materials, etc.

On the carrier 210, the first dielectric layer 121A may be deposited. In example embodiments, the first dielectric layer 121A may comprise a photoimageable dielectric (PID) to be used in a redistribution process. The photoimageable dielectric is a material applicable to a photolithography process to form fine patterns. In example embodiments, the photoimageable dielectric may comprise a polyimide-based photosensitive polymer, a novolac-based photosensitive polymer, polybenzoxazole, a silicon-based polymer, an acrylate-based polymer, or an epoxy-based polymer. In example embodiments, the first dielectric layer 121A may be formed by a spin coating process. After the first dielectric layer 121A is deposited, the first openings OP1 may be formed in the first dielectric layer 121A by performing a photolithography process (exposure and development processes).

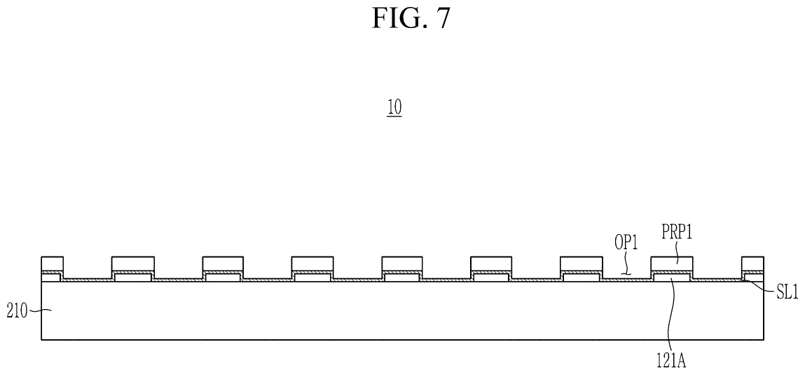

FIG. 7 is a cross-sectional view illustrating a step of forming a seed metal layer SL1 and forming a first photoresist pattern PRP1 on the seed metal layer SL1.

Referring to FIG. 7, the seed metal layer SL1 may conformally be deposited on the upper surface of the carrier 210, the inner walls of the first openings OP1 of the first dielectric layer 121A, and the upper surface of the first dielectric layer 121A. In example embodiments, the seed metal layer SL1 may comprise copper. In example embodiments, the seed metal layer SL1 may comprise a conductive material which can be electroplated. In example embodiments, the seed metal layer SL1 may be formed by electroless plating. In example embodiments, prior to the electroless plating, a cleaning process or a metal catalyst activation pretreatment process may be performed. In example embodiments, the seed metal layer SL1 may be formed by sputtering.

After the seed metal layer SL1 is formed, the first photoresist pattern PRP1 may be formed on the seed metal layer SL1. The first photoresist pattern PRP1 may be formed by forming a photoresist on the seed metal layer SL1 and exposing and developing the photoresist. In example embodiments, the photoresist may be formed through spin coating. In example embodiments, the photoresist may comprise an organic polymer resin comprising a photoactive material. The first photoresist pattern PRP1 may be formed such that the seed metal layer SL1 inside the first openings OP1 is exposed.

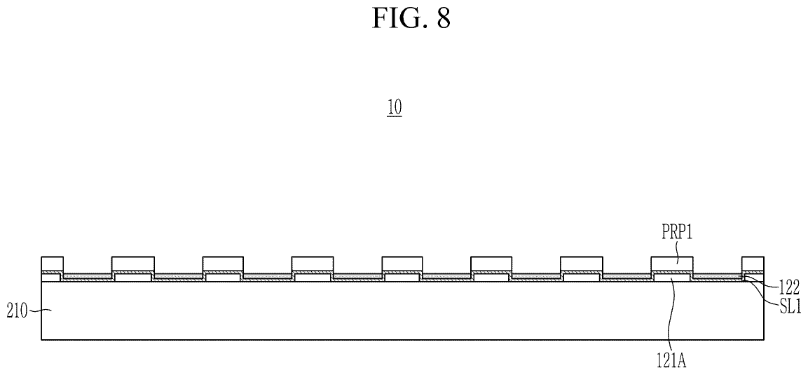

FIG. 8 is a cross-sectional view illustrating a step of forming UBM pads 122 in the first openings OP1 of the first dielectric layer 121A.

Referring to FIG. 8, the UBM pads 122 may be formed in the first openings OP1 of the first dielectric layer 121A. In example embodiments, the UBM pads 122 may be formed by electroplating. The UBM pads 122 may be formed by growing a metal film from the seed metal layer SL1, formed earlier, by electroplating. In example embodiments, after the UBM pads 122 are formed, an annealing process may be performed. In example embodiments, the UBM pads 122 may comprise copper. In other example embodiments, the UBM pads 122 may comprise a conductive material which can be electroplated.

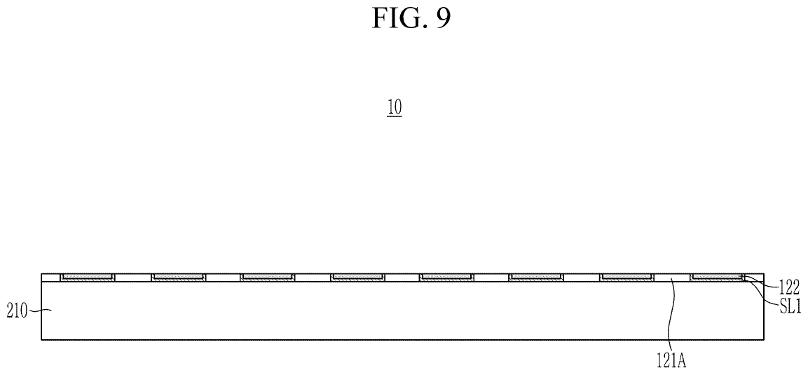

FIG. 9 is a cross-sectional view illustrating a step of removing the first photoresist pattern PRP1 and removing the exposed seed metal layer SL1.

Referring to FIG. 9, the first photoresist pattern PRP1 on the seed metal layer SL1 may be removed, and the exposed seed metal layer SL1 may be removed. In example embodiments, the first photoresist pattern PRP1 may be removed by performing at least one of etching, ashing processes, and strip processes. In example embodiments, the exposed seed metal layer SL1 may be removed by etching.

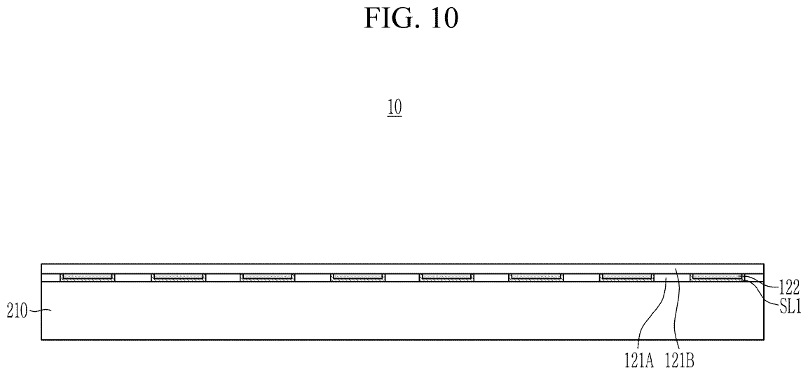

FIG. 10 is a cross-sectional view illustrating a step of depositing a second dielectric layer 121B on the first dielectric layer 121A and the UBM pads 122.

Referring to FIG. 10, the second dielectric layer 121B may be deposited on the first dielectric layer 121A and the UBM pads 122. The second dielectric layer 121B may be formed so as to cover the first dielectric layer 121A and the UBM pads 122. In example embodiments, the second dielectric layer 121B may comprise a photoimageable dielectric (PID) to be used in a redistribution process. In example embodiments, the second dielectric layer 121B may be formed by performing a spin coating process.

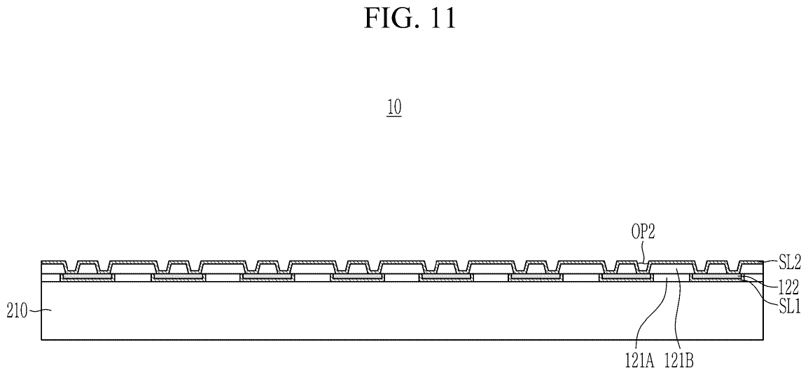

FIG. 11 is a cross-sectional view illustrating a step of forming second openings OP2 in the second dielectric layer 121B and depositing a seed metal layer SL2.

Referring to FIG. 11, the second openings OP2 may be formed in the second dielectric layer 121B by performing a photolithography process (exposure and development processes). Thereafter, the seed metal layer SL2 may be conformally deposited on the exposed surfaces of the UBM pads 122, the inner walls of the second openings OP2 of the second dielectric layer 121B, and the upper surface of the second dielectric layer 121B. In example embodiments, the seed metal layer SL2 may comprise copper. In example embodiments, the seed metal layer SL2 may comprise a conductive material which can be electroplated. In example embodiments, the seed metal layer SL2 may be formed by electroless plating. In example embodiments, prior to the electroless plating, a cleaning process or a metal catalyst activation pretreatment process may be performed. In example embodiments, the seed metal layer SL2 may be formed by sputtering.

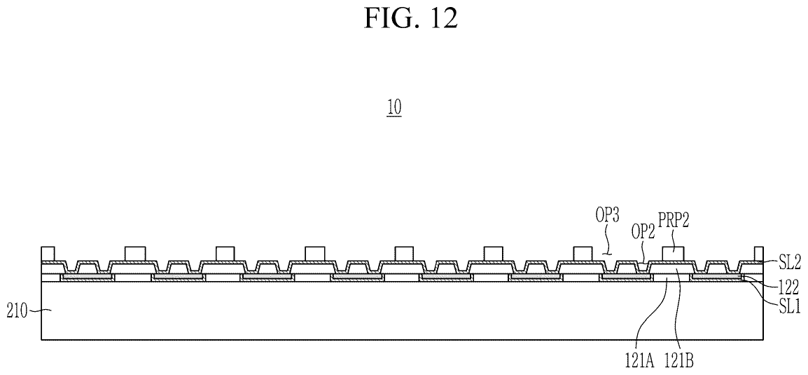

FIG. 12 is a cross-sectional view illustrating a step of forming a second photoresist pattern PRP2 on the seed metal layer SL2.

Referring to FIG. 12, the second photoresist pattern PRP2 may be formed on the seed metal layer SL2. The second photoresist pattern PRP2 may be formed by forming a photoresist on the seed metal layer SL2 and exposing and developing the photoresist. In example embodiments, the photoresist may be formed through spin coating. In example embodiments, the photoresist may comprise an organic polymer resin comprising a photoactive material. The second photoresist pattern PRP2 may include third openings OP3 according to the shape of a first redistribution line 124 to be formed.

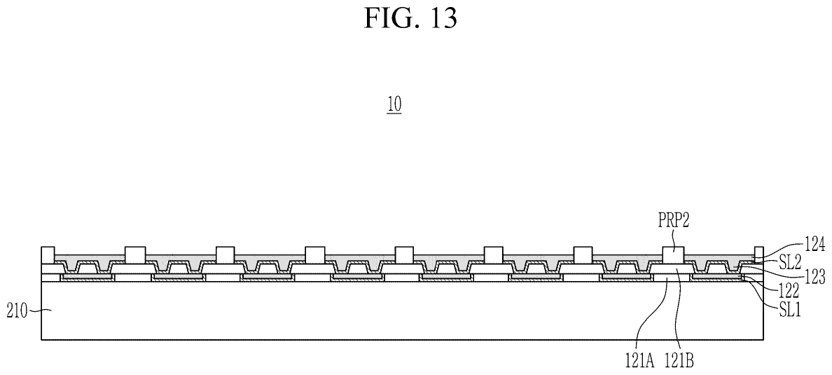

FIG. 13 is a cross-sectional view illustrating a step of forming first vias 123 in the second openings OP2 of the second dielectric layer 121B and forming first redistribution lines 124 in the third openings OP3 of the second photoresist pattern PRP2.

Referring to FIG. 13, the first vias 123 may be formed in the second openings OP2 of the second dielectric layer 121B, and the first redistribution lines 124 may be formed in the third openings OP3 of the second photoresist pattern PRP2. First multiple vias 123 of the first vias 123 and a corresponding first redistribution line 124 of the first redistribution lines 124 may be integrally formed by a single electroplating process. The first vias 123 and the first redistribution lines 124 may be formed by growing a metal film from the seed metal layer SL2, formed earlier, by electroplating. In example embodiments, after the first vias 123 and the first redistribution lines 124 are formed, an annealing process may be performed. In example embodiments, each of the first vias 123 and the first redistribution lines 124 may comprise copper. In other example embodiments, each of the first vias 123 and the first redistribution lines 124 may comprise a conductive material which can be electroplated.

When the size of openings for forming the redistribution lines is large, the openings may not be fully filled even after the electroplating process is performed, and thus, the redistribution lines may have an undulated morphology. This affects fine conductive pattern formation in the subsequent processes, and may cause deterioration of the reliability of the redistribution layer interposer.

According to the present disclosure, on the basis that it is possible to improve the process variation of an electroplating process as the volume of a portion which is a subject of the electroplating increases, a plurality of first vias 123 may be formed between each of the UBM pads 122 and a corresponding first redistribution line 124 of the first redistribution lines 124. As described above, it is possible to increase the volume of the subject of an electroplating process by adding multiple vias (the first vias 123), thereby preventing the first redistribution line 124 from having an undulated morphology, improving the process variation of the electroplating process, and improving the reliability of the interposer 10.

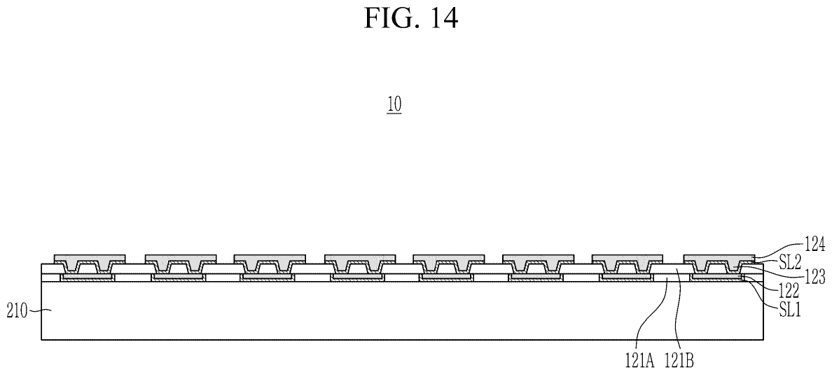

FIG. 14 is a cross-sectional view illustrating a step of removing the second photoresist pattern PRP2 and removing the exposed seed metal layer SL2.

Referring to FIG. 14, the second photoresist pattern PRP2 on the seed metal layer SL2 may be removed, and the exposed seed metal layer SL2 may be removed. In example embodiments, the second photoresist pattern PRP2 may be removed by performing at least one of etching, ashing processes, and strip processes. In example embodiments, the exposed seed metal layer SL2 may be removed by etching.

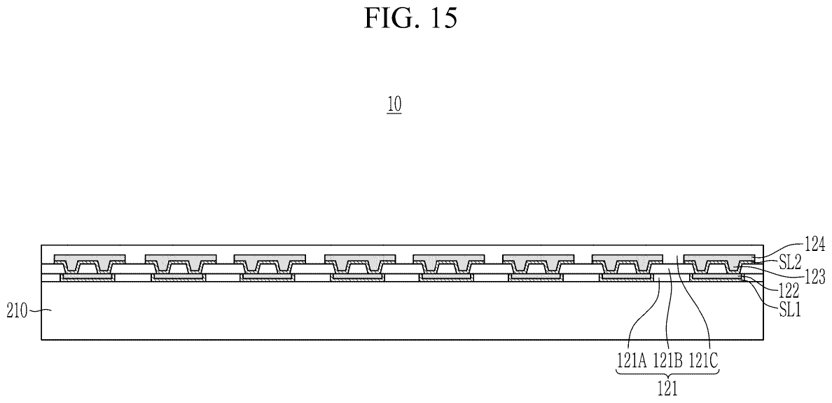

FIG. 15 is a cross-sectional view illustrating a step of depositing a third dielectric layer 121C on the second dielectric layer 121B and the first redistribution lines 124.

Referring to FIG. 15, the third dielectric layer 121C may be deposited on the second dielectric layer 121B and the first redistribution lines 124. The third dielectric layer 121C may be formed so as to cover the second dielectric layer 121B and the first redistribution lines 124. In example embodiments, the third dielectric layer 121C may comprise a photoimageable dielectric (PID) to be used in a redistribution process. In example embodiments, the third dielectric layer 121C may be formed by performing a spin coating process.

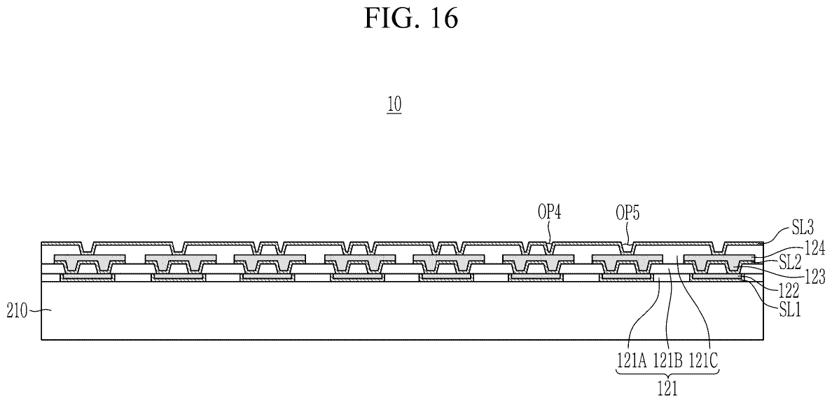

FIG. 16 is a cross-sectional view illustrating a step of forming fourth openings OP4 and fifth openings OP5 in the third dielectric layer 121C and depositing a seed metal layer SL3.

Referring to FIG. 16, the fourth openings OP4 according to the shape of the second vias 125 to be formed in the third dielectric layer 121C, and the fifth openings OP5 according to the shape of the third vias 126 to be formed in the third dielectric layer 121C may be formed by performing a photolithography process (exposure and development processes). Thereafter, the seed metal layer SL3 may be conformally deposited on the exposed surfaces of the first redistribution lines 124, the inner walls of the fourth openings OP4 and the inner walls of the fifth openings OP5 in the third dielectric layer 121C, and the upper surface of the third dielectric layer 121C. In example embodiments, the seed metal layer SL3 may comprise copper. In example embodiments, the seed metal layer SL3 may comprise a conductive material which can be electroplated. In example embodiments, the seed metal layer SL3 may be formed by electroless plating. In example embodiments, prior to the electroless plating, a cleaning process or a metal catalyst activation pretreatment process may be performed. In example embodiments, the seed metal layer SL3 may be formed by sputtering.

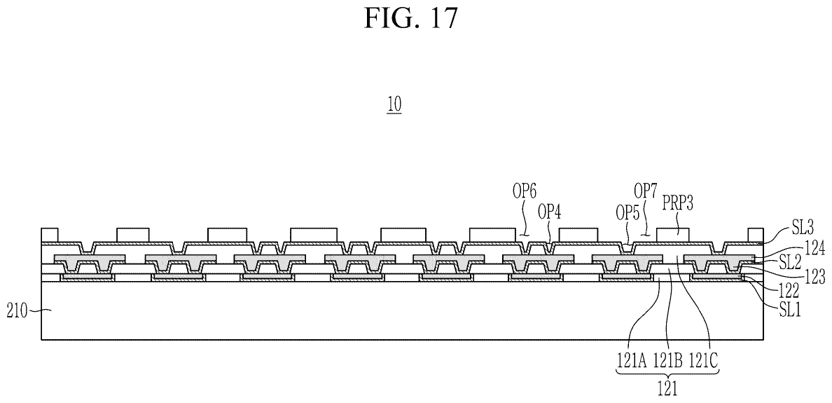

FIG. 17 is a cross-sectional view illustrating a step of forming a third photoresist pattern PRP3 on the seed metal layer SL3.

Referring to FIG. 17, the third photoresist pattern PRP3 may be formed on the seed metal layer SL3. The third photoresist pattern PRP3 may be formed by forming a photoresist on the seed metal layer SL3 and exposing and developing the photoresist. In example embodiments, the photoresist may be formed through spin coating. In example embodiments, the photoresist may comprise an organic polymer resin comprising a photoactive material. The third photoresist pattern PRP3 may include sixth openings OP6 according to the shape of first bonding pads 127 to be formed, and seventh openings OP7 according to the shape of second bonding pads 128 to be formed.

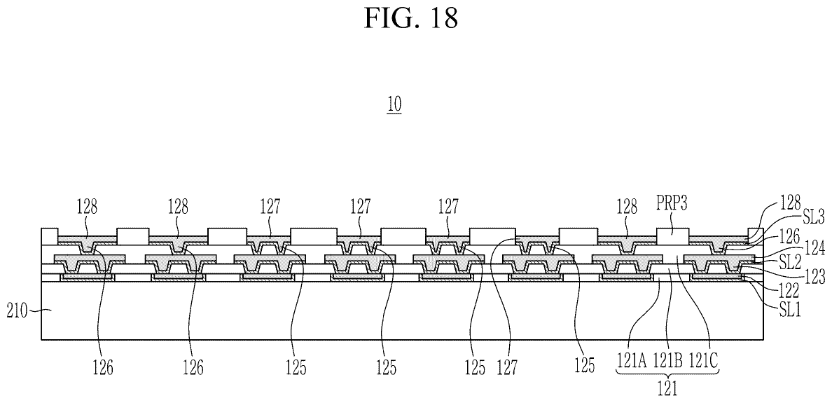

FIG. 18 is a cross-sectional view illustrating a step of forming second vias 125 in the fourth openings OP4 of the third dielectric layer 121C, forming third vias 126 in the fifth openings OP5 of the third dielectric layer 121C, forming first bonding pads 127 in the sixth openings OP6 of the third photoresist pattern PRP3, and forming second bonding pads 128 in the seventh openings OP7 of the third photoresist pattern PRP3.

Referring to FIG. 18, the second vias 125 may be formed in the fourth openings OP4 of the third dielectric layer 121C, and the third vias 126 may be formed in the fifth openings OP5 of the third dielectric layer 121C, and the first bonding pads 127 may be formed in the sixth openings OP6 of the third photoresist pattern PRP3, and the second bonding pads 128 may be formed in the seventh openings OP7 of the third photoresist pattern PRP3. Multiple second vias 125 of the second vias 125 and a corresponding first bonding pad 127 of the first bonding pads 127 may be integrally formed by a single electroplating process. Each of the third vias 126 and a corresponding second bonding pad 128 of the second bonding pads 128 may be integrally formed by a single electroplating process. The second vias 125, the third vias 126, the first bonding pads 127, and the second bonding pads 128 may be formed by growing a metal film from the seed metal layer SL3, formed earlier, by electroplating. In example embodiments, after the second vias 125, the third vias 126, the first bonding pads 127, and the second bonding pads 128 are formed, an annealing process may be performed. In example embodiments, each of the second vias 125, the third vias 126, the first bonding pads 127, and the second bonding pads 128 may comprise copper. In other example embodiments, each of the second vias 125, the third vias 126, the first bonding pads 127, and the second bonding pads 128 may comprise a conductive material which can be electroplated.

As the height of a conductive post in the interposer increases, the process needs to be repeatedly performed, and an increased aspect ratio of conductive posts may cause a risk of reducing the yield of redistribution layer interposers. In order to solve these problems, the height of conductive posts may be reduced by forming bonding pads below the conductive posts. However, since the volume or area of a bonding pad which is formed below a conductive post is larger than the volume or area of a bonding pad which is formed below a bridge die, the process variation of bonding pads formed below the bridge die after an electroplating process is performed may worsen.

According to the present disclosure, multiple second vias 125 may be disposed between each of the first redistribution lines 124 and each of the first bonding pads 127 of the bridge die 130, and one third via 126 may be disposed between each of the first redistribution lines 124 and each of the second bonding pads 128. Accordingly, the volume or area of the first bonding pad 127 smaller than the volume or area of the second bonding pad 128 can be offset by the addition of the multiple second vias 125 in the course of performing an electroplating process on the first bonding pad 127 and the multiple second vias 125, and the second bonding pad 128 and one third via 126 simultaneously, and it is possible to prevent the process variation of the first bonding pads 127 from worsening when the electroplating process is performed.

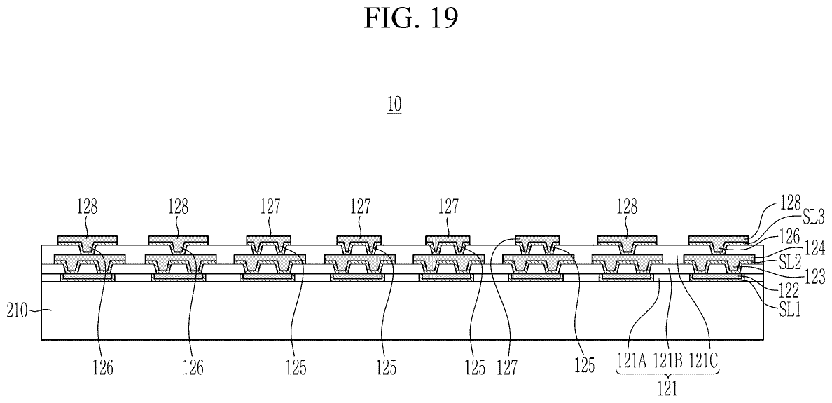

FIG. 19 is a cross-sectional view illustrating a step of removing the third photoresist pattern PRP3 and removing the exposed seed metal layer SL3.

Referring to FIG. 19, the third photoresist pattern PRP3 on the seed metal layer SL3 may be removed, and the exposed seed metal layer SL3 may be removed. In example embodiments, the third photoresist pattern PRP3 may be removed by performing at least one of etching, ashing processes, and strip processes. In example embodiments, the exposed seed metal layer SL3 may be removed by etching.

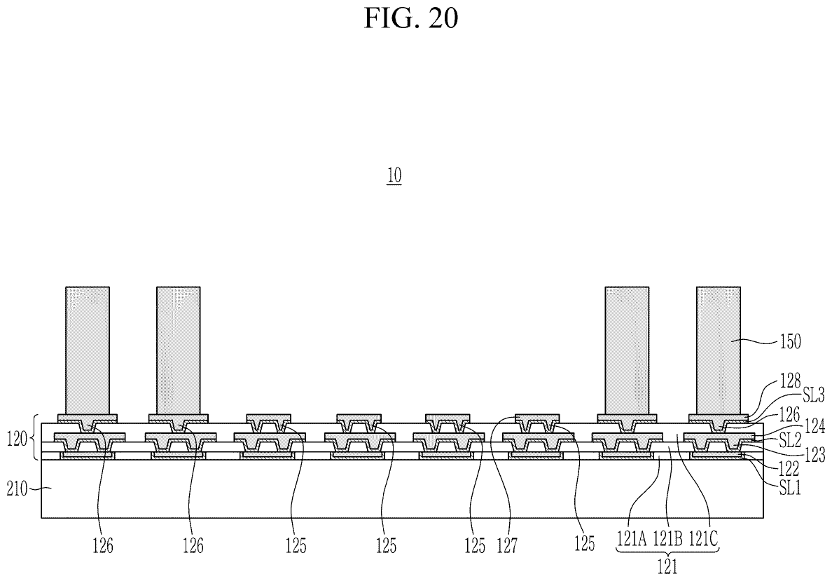

FIG. 20 is a cross-sectional view illustrating a step of forming conductive posts 150 on a lower redistribution structure 120.

Referring to FIG. 20, conductive posts 150 may be formed on the second bonding pads 128 of the lower redistribution structure 120. The conductive posts 150 may be formed by performing a photolithography process (exposure and development) and a depositing process. In example embodiments, the depositing process for the conductive posts 150 may be performed by sputtering. In other example embodiments, the depositing process for the conductive posts 150 may be performed by an electroplating process. In example embodiments, the conductive posts 150 may comprise at least one of copper, aluminum, tungsten, nickel, gold, silver, chromium, antimony, tin, titanium, and alloys thereof.

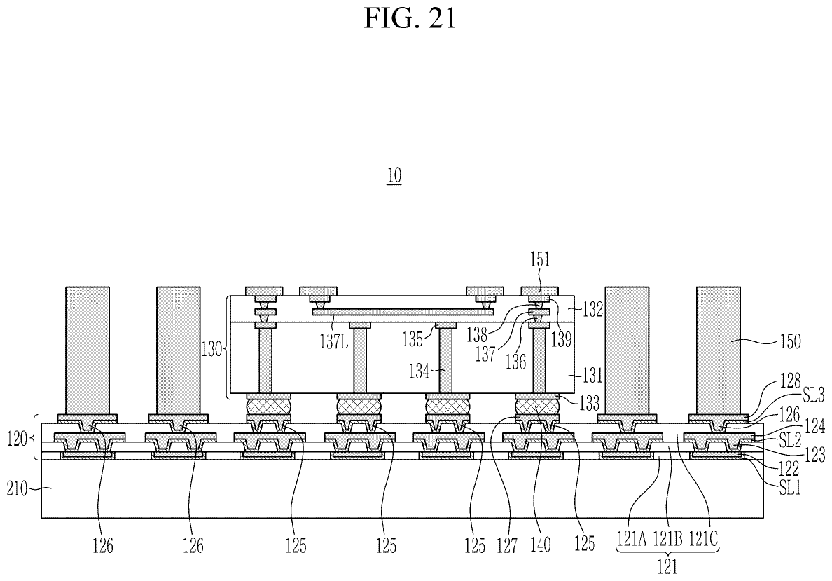

FIG. 21 is a cross-sectional view illustrating a step of mounting the bridge die 130 on the lower redistribution structure 120.

Referring to FIG. 21, the bridge die 130 may be mounted on the lower redistribution structure 120. In example embodiments, the bridge die 130 may be bonded to the upper surface of the lower redistribution structure 120 by performing a flip-chip bonding process. The bridge die 130 may be bonded to the first bonding pads 127 of the lower redistribution structure 120 by the first connection members 140, whereby the bridge die 130 and the lower redistribution structure 120 may be electrically connected. In example embodiments, the first connection members 140 may include micro bumps. In example embodiments, the first connection members 140 may comprise at least one of tin, silver, lead, nickel, copper, and alloys thereof.

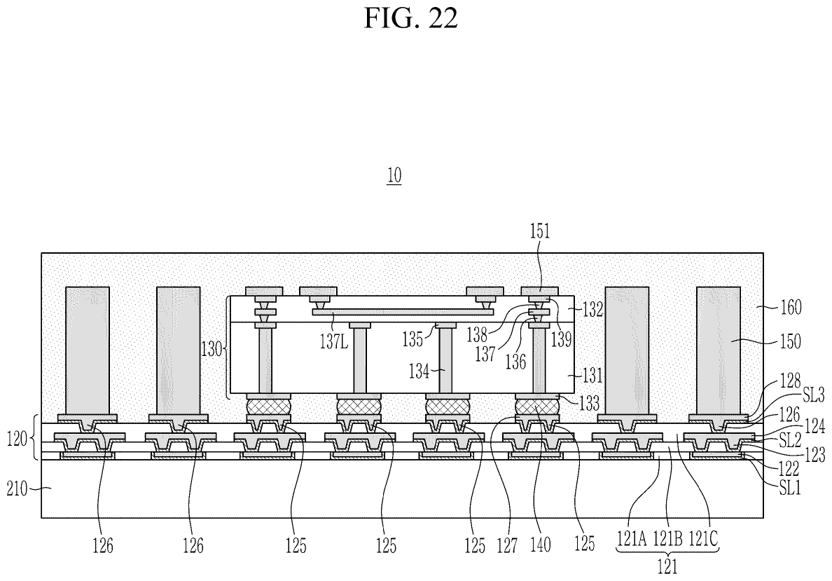

FIG. 22 is a cross-sectional view illustrating a step of encapsulating the bridge die 130, the first connection members 140, the conductive posts 150, and the connection terminals 151 on the lower redistribution structure 120.

Referring to FIG. 22, the bridge die 130, the first connection members 140, the conductive posts 150, and the connection terminals 151 may be encapsulated on the lower redistribution structure 120 by the first molding material 160. In example embodiments, the process of performing encapsulating by the first molding material 160 may include a compression molding or transfer molding process. In example embodiments, the first molding material 160 may comprise an epoxy molding compound (EMC).

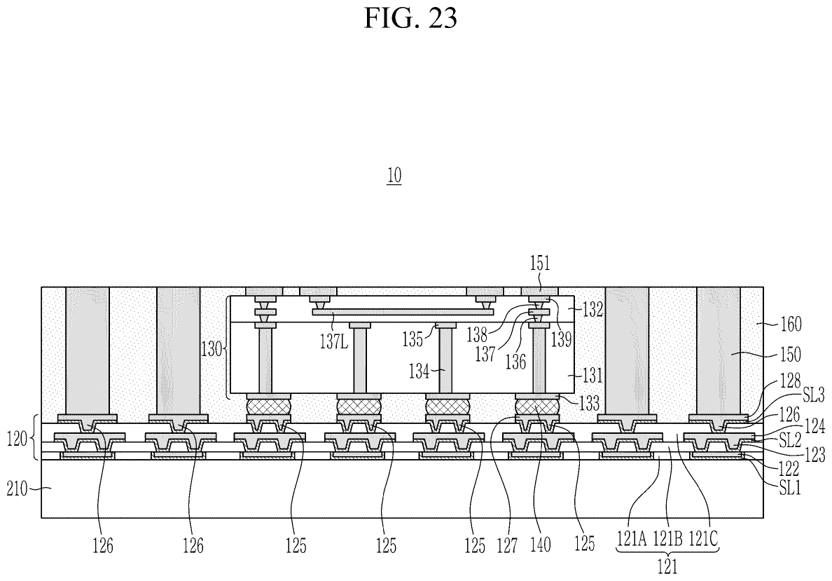

FIG. 23 is a cross-sectional view illustrating a step of performing a chemical mechanical planarization (CMP) process on the first molding material 160.

Referring to FIG. 23, by performing the chemical mechanical planarization (CMP) process to level the upper surface of the first molding material 160, the upper surface of the first molding material 160 may be planarized. After the chemical mechanical planarization (CMP) process is performed, the upper surfaces of the conductive posts 150, and the upper surfaces of the connection terminals 151 may be exposed and/or may be coplanar with the upper surface of the first molding material 160.

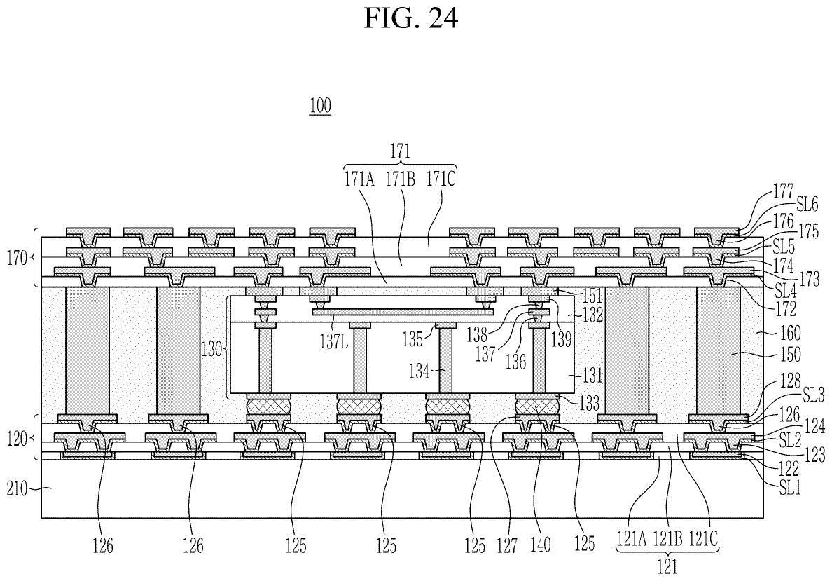

FIG. 24 is a cross-sectional view illustrating a step of forming an upper redistribution structure 170 on the conductive posts 150, the connection terminals 151, and the first molding material 160.

Referring to FIG. 24, a fourth dielectric layer 171A may be deposited on the conductive posts 150, the connection terminals 151, and the first molding material 160. After the fourth dielectric layer 171A is deposited, openings may be formed in the fourth dielectric layer 171A by performing a photolithography process (exposure and development processes).

After the openings are formed in the fourth dielectric layer 171A, a seed metal layer SL4 may be conformally formed on the upper surfaces of the conductive posts 150, the upper surfaces of the connection terminals 151, the inner walls of the openings of the fourth dielectric layer 171A, and the upper surface of the fourth dielectric layer 171A. After the seed metal layer SL4 is formed, a photoresist pattern may be formed on the seed metal layer SL4.

After the photoresist pattern is formed, a metal film may be grown from the seed metal layer SL4, formed earlier, by electroplating, thereby forming fourth vias 172 in the openings of the fourth dielectric layer 171A and forming second redistribution lines 173 in the photoresist pattern. Each of the fourth vias 172 and a corresponding second redistribution line 173 of the second redistribution lines 173 may be integrally formed by a single electroplating process. In example embodiments, after the fourth vias 172 and the second redistribution lines 173 are formed, an annealing process may be performed. Thereafter, the photoresist pattern and the exposed seed metal layer SL4 may be removed.

After the exposed seed metal layer SL4 is removed, a fifth dielectric layer 171B may be deposited on the fourth dielectric layer 171A and the second redistribution lines 173. The fifth dielectric layer 171B may be formed so as to cover the fourth dielectric layer 171A and the second redistribution lines 173.

After the fifth dielectric layer 171B is deposited, openings according to the shape of fifth vias 174 to be formed in the fifth dielectric layer 171B may be formed by performing a photolithography process (exposure and development processes).

After the openings are formed in the fifth dielectric layer 171B, a seed metal layer SL5 may be conformally formed on the exposed surfaces of the second redistribution lines 173, the inner walls of the openings of the fifth dielectric layer 171B, and the upper surface of the fifth dielectric layer 171B. After the seed metal layer SL5 is formed, a photoresist pattern may be formed on the seed metal layer SL5.

After the photoresist pattern is formed, a metal film may be grown from the seed metal layer SL5, formed earlier, by electroplating, thereby forming fifth vias 174 in the openings of the fifth dielectric layer 171B and forming third redistribution lines 175 in the photoresist pattern. Each of the fifth vias 174 and a corresponding third redistribution line 175 of the third redistribution lines 175 may be integrally formed by a single electroplating process. In example embodiments, after the fifth vias 174 and the third redistribution lines 175 are formed, an annealing process may be performed. Thereafter, the photoresist pattern and the exposed seed metal layer SL5 may be removed.

After the exposed seed metal layer SL5 is removed, a sixth dielectric layer 171C may be deposited on the fifth dielectric layer 171B and the third redistribution lines 175. The sixth dielectric layer 171C may be formed so as to cover the fifth dielectric layer 171B and the third redistribution lines 175.

After the sixth dielectric layer 171C is deposited, openings according to the shape of sixth vias 176 to be formed in the sixth dielectric layer 171C may be formed by performing a photolithography process (exposure and development processes).

After the openings are formed in the sixth dielectric layer 171C, a seed metal layer SL6 may be conformally deposited on the exposed surfaces of the third redistribution lines 175, the inner walls of the openings of the sixth dielectric layer 171C, and the upper surface of the sixth dielectric layer 171C. After the seed metal layer SL6 is formed, a photoresist pattern is formed on the seed metal layer SL6.

Sixth vias 176 may be formed in the openings of the sixth dielectric layer 171C, and third bonding pads 177 may be formed in the photoresist pattern. Each of the sixth vias 176 and a corresponding third bonding pad 177 of the third bonding pads 177 may be integrally formed by a single electroplating process. A metal film may be grown from the seed metal layer SL6, formed earlier, by electroplating, thereby forming the sixth vias 176 and the third bonding pads 177. In example embodiments, after the sixth vias 176 and the third bonding pads 177 are formed, an annealing process may be performed. Thereafter, the photoresist pattern and the exposed seed metal layer SL6 may be removed.

In example embodiments, each of the fourth dielectric layer 171A, the fifth dielectric layer 171B, and the sixth dielectric layer 171C may comprise a photoimageable dielectric (PID) to be used in a redistribution process. In example embodiments, each of the fourth dielectric layer 171A, the fifth dielectric layer 171B, and the sixth dielectric layer 171C may be formed by performing a spin coating process. In example embodiments, each of the seed metal layers SL4, SL5, and SL6 may comprise copper. In example embodiments, each of the seed metal layers SL4, SL5, and SL6 may comprise a conductive material which can be electroplated. In example embodiments, each of the seed metal layers SL4, SL5, and SL6 may be formed by electroless plating. In example embodiments, prior to the electroless plating, a cleaning process or a metal catalyst activation pretreatment process may be performed. In example embodiments, each of the seed metal layers SL4, SL5, and SL6 may be formed by sputtering. In example embodiments, each of the fourth vias 172, the second redistribution lines 173, the fifth vias 174, the third redistribution lines 175, the sixth vias 176, and the third bonding pads 177 may comprise copper. In other example embodiments, each of the fourth vias 172, the second redistribution lines 173, the fifth vias 174, the third redistribution lines 175, the sixth vias 176, and the third bonding pads 177 may comprise a conductive material which can be electroplated. In example embodiments, the photoresist pattern may be removed by performing at least one of etching, ashing processes, and strip processes. In example embodiments, the exposed seed metal layers SL4, SL5, and SL6 may be removed by etching.

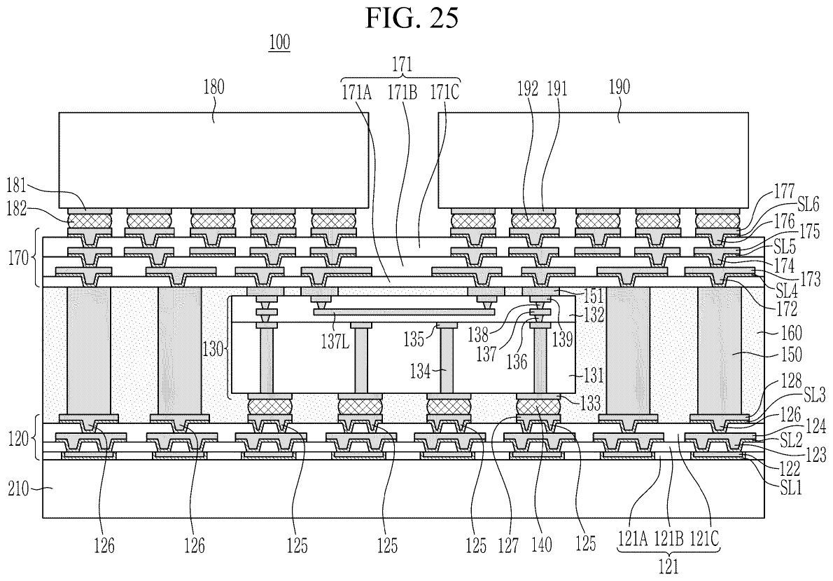

FIGS. 25 to 30 are cross-sectional views for explaining a method of manufacturing the semiconductor package 100 of FIG. 1.

FIG. 25 is a cross-sectional view illustrating a step of mounting the first semiconductor die 180 and the second semiconductor die 190 on the upper redistribution structure 170 of the interposer 10.

Referring to FIG. 25, the first semiconductor die 180 and the second semiconductor die 190 may be mounted on the upper redistribution structure 170. In example embodiments, each of the first semiconductor die 180 and the second semiconductor die 190 may be bonded to the upper surface of the upper redistribution structure 170 by performing a flip-chip bonding process. The first semiconductor die 180 may be bonded to the third bonding pads 177 of the upper redistribution structure 170 by the second connection members 182, and the second semiconductor die 190 may be bonded to the third bonding pads 177 of the upper redistribution structure 170 by the third connection members 192, whereby the first semiconductor die 180 and the upper redistribution structure 170 may be electrically connected and the second semiconductor die 190 and the upper redistribution structure 170 may be electrically connected. In example embodiments, each of the second connection members 182 and the third connection members 192 may include a micro bump. In example embodiments, each of the second connection members 182 and the third connection members 192 may comprise at least one of tin, silver, lead, nickel, copper, and alloys thereof.

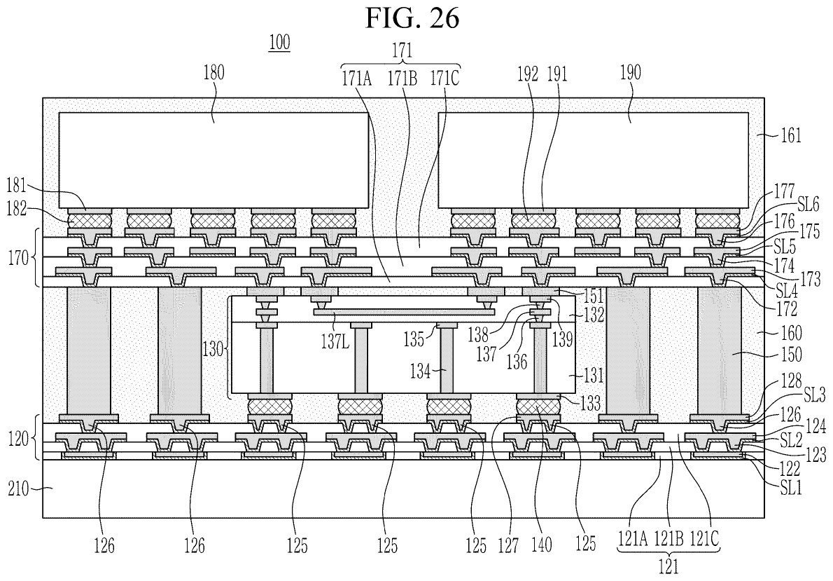

FIG. 26 is a cross-sectional view illustrating a step of encapsulating the first semiconductor die 180, the second connection pads 181, the second connection members 182, the second semiconductor die 190, the third connection pads 191, and the third connection members 192 on the upper redistribution structure 170.

Referring to FIG. 26, the first semiconductor die 180, the second connection pads 181, the second connection members 182, the second semiconductor die 190, the third connection pads 191, and the third connection members 192 may be encapsulated on the upper redistribution structure 170 by the second molding material 161. In example embodiments, the process of performing encapsulating by the second molding material 161 may include a compression molding or transfer molding process. In example embodiments, the second molding material 161 may comprise an epoxy molding compound (EMC).

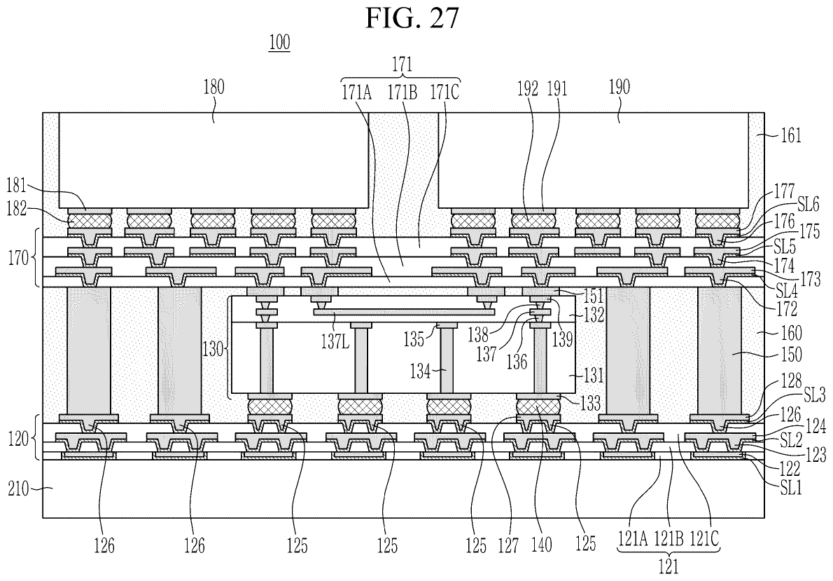

FIG. 27 is a cross-sectional view illustrating a step of performing a chemical mechanical planarization (CMP) process on the second molding material 161.

Referring to FIG. 27, by performing the chemical mechanical planarization (CMP) process to level the upper surface of the second molding material 161, the upper surface of the second molding material 161 may be planarized. After the chemical mechanical planarization (CMP) process is performed, the upper surface of the first semiconductor die 180 and the upper surface of the second semiconductor die 190 may be exposed and/or may be coplanar with the upper surface of the second molding material 161.

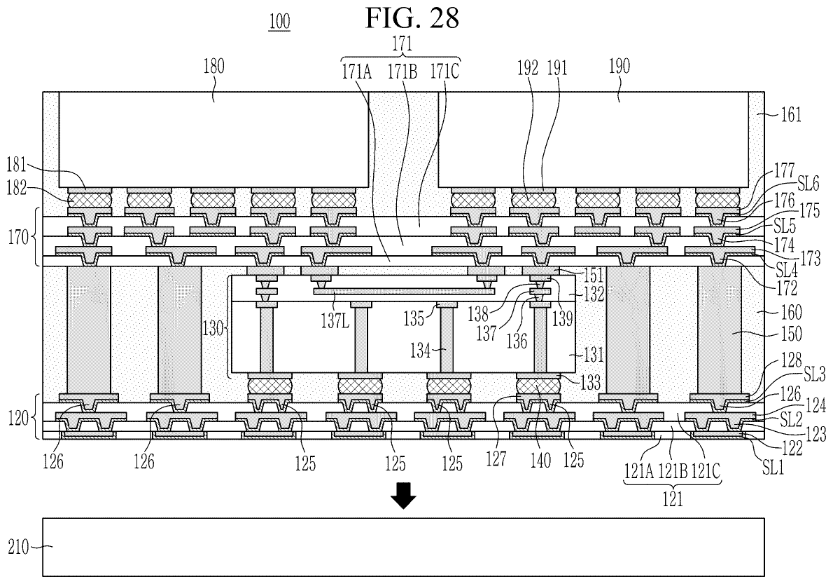

FIG. 28 is a cross-sectional view illustrating a step of removing the carrier 210 from the lower redistribution structure 120 of the interposer 10.

Referring to FIG. 28, the carrier 210 may be removed from the lower surface of the lower redistribution structure 120.

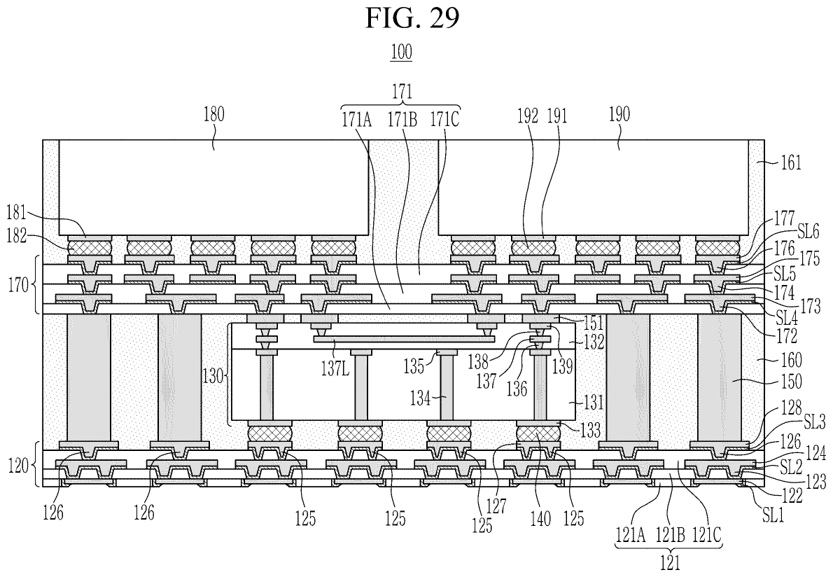

FIG. 29 is a cross-sectional view illustrating a step of performing etching on the seed metal layer SL1 on the lower surface of the lower redistribution structure 120.

Referring to FIG. 29, etching may be performed on the seed metal layer SL1 on the lower surface of the lower redistribution structure 120 such that the lower surfaces of the UBM pads 122 may be exposed.

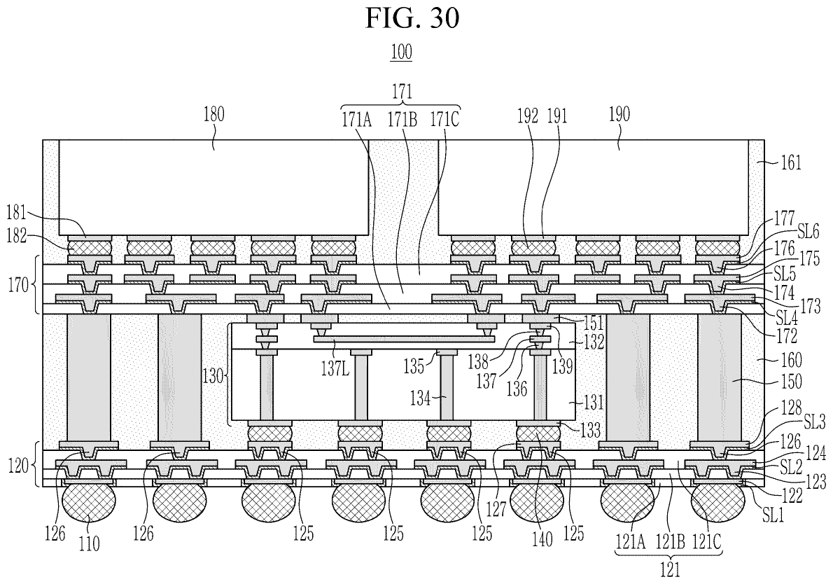

FIG. 30 is a cross-sectional view illustrating a step of forming the external connection members 110 below the lower surfaces of the UBM pads 122.

Referring to FIG. 30, the external connection members 110 may be formed below the lower surfaces of the UBM pads 122. In example embodiments, the external connection members 110 may include solder balls or bumps. In example embodiments, the external connection members 110 may comprise at least one of tin, silver, lead, nickel, copper, and alloys thereof.

While the present disclosure has been described in connection with what is presently considered to be practical example embodiments, it is to be understood that the present disclosure is not limited to the disclosed example embodiments. On the contrary, it is intended to cover various modifications and equivalent arrangements included within the spirit and scope of the appended claims.

What is claimed is:

1. An interposer comprising:
a redistribution structure;
a bridge die on the redistribution structure; and
a plurality of conductive posts adjacent the bridge die and on the redistribution structure,
wherein the redistribution structure includes:
a dielectric layer;
a plurality of redistribution lines in the dielectric layer;
a plurality of vias on the plurality of redistribution lines and in the dielectric layer;
a plurality of first bonding pads on the dielectric layer and the plurality of vias, and each of the plurality of first bonding pads is connected to the bridge die; and
a plurality of second bonding pads on the dielectric layer and the plurality of vias and adjacent the plurality of first bonding pads, and each of the plurality of second bonding pads is connected to a corresponding conductive post of the plurality of conductive posts, and
the number of vias disposed between each of the plurality of redistribution lines and a corresponding first bonding pad of the plurality of first bonding pads is two or more, and
the number of vias disposed between each of the plurality of redistribution lines and a corresponding second bonding pad of the plurality of second bonding pads is one.

2. The interposer of claim 1, wherein:
each of the plurality of first bonding pads has a first width in a horizontal direction,
each of the plurality of second bonding pads has a second width in the horizontal direction, and
the first width is smaller than the second width.

3. The interposer of claim 1, wherein:
each of the plurality of first bonding pads has a first thickness in a vertical direction,
each of the plurality of second bonding pads has a second thickness in the vertical direction, and
the first thickness is equal to the second thickness.

4. The interposer of claim 1, wherein:
each of the plurality of second bonding pads has a second width in a horizontal direction,
each of the plurality of conductive posts has a third width in the horizontal direction, and
the second width is larger than the third width.

5. The interposer of claim 1, further comprising:
a plurality of micro bumps between the redistribution structure and the bridge die.

6. An interposer comprising:
a first redistribution structure;
a bridge die on the first redistribution structure;
a plurality of conductive posts adjacent the bridge die and on the first redistribution structure;
a second redistribution structure on the bridge die and the plurality of conductive posts; and
a molding material between the first redistribution structure and the second redistribution structure so as to at least partially cover the bridge die and the plurality of conductive posts,
wherein the first redistribution structure includes:
a dielectric layer;
a plurality of UBM pads in the dielectric layer;
a plurality of first vias on the plurality of UBM pads and in the dielectric layer;
a plurality of redistribution lines on the plurality of first vias and in the dielectric layer;
a plurality of second vias on the plurality of redistribution lines and in the dielectric layer;
a plurality of third vias on the plurality of redistribution lines, in the dielectric layer, and adjacent the plurality of second vias;
a plurality of first bonding pads on the dielectric layer and the plurality of second vias with each of the plurality of first bonding pads connected to the bridge die; and
a plurality of second bonding pads on the dielectric layer and the plurality of third vias and adjacent the plurality of first bonding pads, with each of the plurality of second bonding pads connected to a corresponding conductive post of the plurality of conductive posts, and
the number of first vias disposed between each of the plurality of UBM pads and a corresponding redistribution line of the plurality of redistribution lines is two or more, and
the number of second vias disposed between each of the plurality of redistribution lines and a corresponding first bonding pad of the plurality of first bonding pads is two or more, and
the number of third vias disposed between each of the plurality of redistribution lines and a corresponding second bonding pad of the plurality of second bonding pads is one.

7. The interposer of claim 6, wherein:
the number of first vias disposed between each of the plurality of UBM pads and a corresponding redistribution line of the plurality of redistribution lines is four.

8. The interposer of claim 6, wherein:
the number of second vias disposed between each of the plurality of redistribution lines and a corresponding first bonding pad of the plurality of first bonding pads is four.

9. The interposer of claim 6, wherein:
an upper surface of each of the plurality of first vias has a first width in a horizontal direction,
an upper surface of each of the plurality of second vias has a second width in the horizontal direction, and
the first width is larger than the second width.

10. The interposer of claim 6, wherein:
an upper surface of each of the plurality of second vias has a second width in a horizontal direction,
an upper surface of each of the plurality of third vias has a third width in the horizontal direction, and
the third width is larger than the second width.

11. The interposer of claim 6, wherein:
an upper surface of each of the plurality of first vias has a first width in a horizontal direction,
an upper surface of each of the plurality of third vias has a third width in the horizontal direction, and
the first width is equal to the third width.

12. The interposer of claim 6, wherein:
the plurality of second vias do not vertically overlap the plurality of first vias.

13. The interposer of claim 6, wherein:
the plurality of third vias do not vertically overlap the plurality of first vias.

14. A semiconductor package comprising:
a redistribution layer interposer;
a first semiconductor die on the redistribution layer interposer; and
a second semiconductor die adjacent the first semiconductor die and on the redistribution layer interposer,
wherein the redistribution layer interposer includes:
a first redistribution structure;
a bridge die on the first redistribution structure;
a plurality of conductive posts adjacent the bridge die and on the first redistribution structure;
a second redistribution structure on the bridge die and the plurality of conductive posts; and
a molding material between the first redistribution structure and the second redistribution structure and at least partially covering the bridge die and the plurality of conductive posts, and
the first redistribution structure includes:
a dielectric layer;
a plurality of redistribution lines in the dielectric layer;
a plurality of vias on the plurality of redistribution lines and in the dielectric layer;
a plurality of first bonding pads on the dielectric layer and the plurality of vias and each of the plurality of first bonding pads is connected to the bridge die; and
a plurality of second bonding pads on the dielectric layer and the plurality of vias and adjacent the plurality of first bonding pads, and each of the plurality of second bonding pads is connected to a corresponding conductive post of the plurality of conductive posts, and
the number of vias disposed between each of the plurality of redistribution lines and a corresponding first bonding pad of the plurality of first bonding pads is two or more, and
the number of vias disposed between each of the plurality of redistribution lines and a corresponding second bonding pad of the plurality of second bonding pads is one.

15. The semiconductor package of claim 14, wherein:
the bridge die electrically connects the first semiconductor die to the second semiconductor die.

16. The semiconductor package of claim 14, wherein:
the bridge die includes a silicon bridge.

17. The semiconductor package of claim 14, wherein:
the bridge die electrically connects the second redistribution structure to the first redistribution structure.

18. The semiconductor package of claim 14, wherein:
the bridge die includes a plurality of through-silicon vias.

19. The semiconductor package of claim 14, wherein:
the first semiconductor die includes a logic die.

20. The semiconductor package of claim 14, wherein:
the second semiconductor die includes a high bandwidth memory (HBM).
